(19) United States
(12) Patent Application Publication
(10) Pub. No.: US 2026/0088055 A1
(43) Pub. Date: Mar. 26, 2026

(54) MEMORY DEVICE

(71) Applicant: Kioxia Corporation, Tokyo (JP)

(72) Inventors: Kenichi HAGA, Yokkaichi Mie (JP); Tomoya SANUKI, Yokohama Kanagawa (JP); Keisuke NAKATSUKA, Kuwana Mie (JP); Takayuki MIYAZAKI, Tokyo (JP)

(73) Assignee: Kioxia Corporation, Tokyo (JP)

(21) Appl. No.: 19/059,387

(22) Filed: Feb. 21, 2025

(30) Foreign Application Priority Data
Sep. 20, 2024 (JP) 2024-163518

(51) Int. Cl. G11C 5/06; G11C 11/4096; H10B 12/00

(52) U.S. Cl. CPC G11C 5/063; G11C 11/4096; H10B 12/02; H10B 12/30

(57) ABSTRACT

A first conductor extends in a first direction. A first semiconductor surrounds the first conductor along a first plane intersecting the first direction. A first insulator surrounds the first semiconductor along the first plane. A second conductor surrounds the first insulator along the first plane. A third conductor is located farther in the first direction than the first semiconductor and surrounds the first conductor along the first plane. A second insulator is between the first semiconductor and the third conductor.

### CROSS-REFERENCE TO RELATED APPLICATION

This application is based upon and claims the benefit of priority from Japanese Patent Application No. 2024-163518, filed Sep. 20, 2024, the entire contents of which are incorporated herein by reference.

### FIELD

Embodiments described herein relate generally to a memory device.

### BACKGROUND

A dynamic random access memory (DRAM) is known as a memory device. Memory cells of the DRAM each include a capacitor and a transistor. To increase a storage capacity of the DRAM, the memory cells are required to decrease in size.

### BRIEF DESCRIPTION OF THE DRAWINGS

FIG. 1 illustrates components and coupling of the components of a memory device of a first embodiment.

FIG. 2 illustrates components and coupling of the components of a memory cell of the memory device of the first embodiment.

FIG. 3 is a perspective view of a structure of a part of the memory device of the first embodiment.

FIG. 4 illustrates components and coupling of components of a part of the memory device of the first embodiment.

FIG. 5 illustrates a layout of a components of a part of the memory device of the first embodiment.

FIGS. 6 to 8 each illustrate a cross-sectional structure of a part of the memory device of the first embodiment.

FIG. 9 illustrates a voltage applied to an interconnect during an operation of the memory device of the first embodiment.

FIGS. 10 to 39 each illustrate a state during manufacturing of the memory device of the first embodiment.

FIGS. 40 to 42 each illustrate a cross-sectional structure of part of a memory device of a second embodiment.

FIGS. 43 to 48 illustrate a state during manufacturing of the memory device of the second embodiment.

FIGS. 49 to 51 each illustrate a cross-sectional structure of part of a memory device of a third embodiment.

FIGS. 52 to 58 each illustrate a state during manufacturing of the memory device of the third embodiment.

FIGS. 59 to 62 each illustrate a cross-sectional structure of part of the memory device of the third embodiment.

FIGS. 63 to 65 each illustrate a state during manufacturing of the memory device of the third embodiment.

FIGS. 66 and 67 each illustrate a cross-sectional structure of part of a memory device of a fourth embodiment.

FIGS. 68 and 69 each illustrate a state during manufacturing of the memory device of the fourth embodiment.

FIGS. 70 to 72 each illustrate a cross-sectional structure of part of a memory device of a fifth embodiment.

FIGS. 73 to 76 each illustrate a state during manufacturing of the memory device of the fifth embodiment.

FIG. 77 illustrates a cross-sectional structure of part of a memory device of a sixth embodiment.

FIG. 78 illustrates a cross-sectional structure of part of a memory device of a seventh embodiment.

FIGS. 79 to 93 each illustrate a state during manufacturing of the memory device of the seventh embodiment.

### DETAILED DESCRIPTION

In general, according to one embodiment, a memory device includes a first conductor, a first semiconductor, a first insulator, a second conductor, a third conductor, and a second insulator. The first conductor extends in a first direction. The first semiconductor surrounds the first conductor along a first plane intersecting the first direction. The first insulator surrounds the first semiconductor along the first plane. The second conductor surrounds the first insulator along the first plane. The third conductor is located farther in the first direction than the first semiconductor and surrounds the first conductor along the first plane. The second insulator is between the first semiconductor and the third conductor.

Embodiments will now be described with reference to the figures. In order to distinguish components having substantially the same function and configuration in an embodiment or over different embodiments from each other, an additional numeral or letter may be added to the end of each reference numeral or letter. In the following description, in an embodiment following an embodiment that is already described, different points from the already described embodiment are mainly described. The entire description of a particular embodiment applies to another embodiment unless an explicit mention is made otherwise, or an obvious elimination is involved.

The figures are schematic, and the relation between the thickness and the area of a plane of a layer and the ratio of thicknesses of layers may differ from those in actuality. The figures may include components which differ in relations and/or ratios of dimensions in different figures.

The specification and the claims, when mentioning that a particular (first) component is “coupled” to another (second) component, intend to cover both the form of the first component directly coupled to the second component and the form of the first component coupled to the second component via one or more components which are always or selectively conductive.

Embodiments will be described using a three-dimensional orthogonal coordinate system. A direction of an x axis is referred to as an X direction. A direction opposite to the X direction is referred to as a-X direction. A direction of a y axis is referred to as a Y direction. A direction opposite to the Y direction is referred to as a-Y direction. A direction of a z axis is referred to as a Z direction, and up indicates the Z direction. A direction opposite to the Z direction is referred to as a-Z direction.

### 1. First Embodiment

### 1.1. Configuration (Structure)

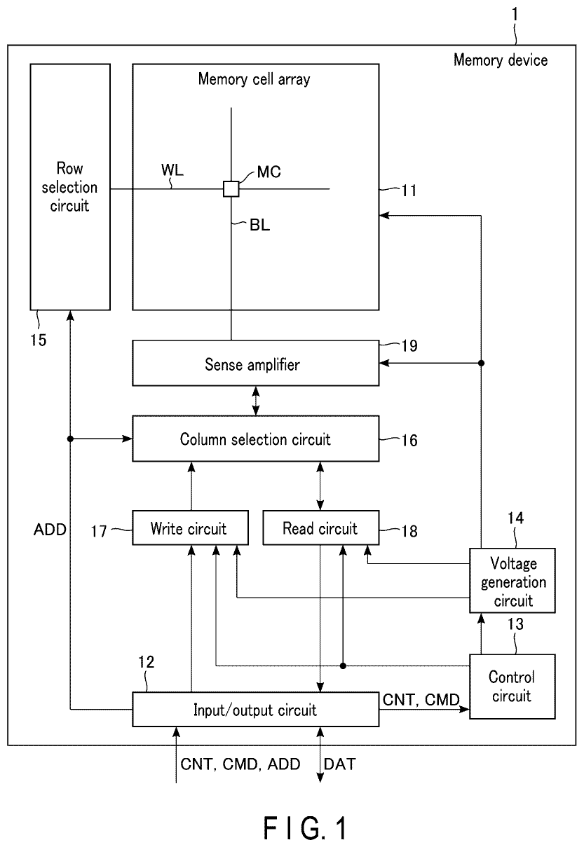

FIG. 1 illustrates components and coupling of the components of a memory device of a first embodiment. A memory device 1 is a device that stores data. The memory device is controlled by an external memory controller. The memory device 1 includes a memory cell array 11, an input/output circuit 12, a control circuit 13, a voltage generation circuit 14, a row selection circuit 15, a column selection circuit 16, a write circuit 17, a read circuit 18, and a sense amplifier 19.

The memory cell array 11 is a set of arrayed memory cells MC. Each memory cell MC is capable of storing 1-bit data. A plurality of word lines WL and a plurality of bit lines BL are located in the memory cell array 11. Each memory cell MC is coupled to a single bit line BL and a single word line WL. The memory cell MC is coupled between the bit line BL and the plate line PL (not illustrated). The word line WL is associated with a row. The bit line BL is associated with a column. Through selection of a single row and a single column, a single memory cell MC is specified.

The input/output circuit 12 is a circuit that inputs and outputs data and signals. The input/output circuit 12 receives, from outside the memory device 1, and, in one example, from a memory controller, a control signal CNT, a command CMD, an address signal ADD, and data DAT. The input/output circuit 12 outputs data DAT.

The control circuit 13 is a circuit that controls the operation of the memory device 1. The control circuit 13 receives a command CMD and a control signal CNT from the input/output circuit 12. The control circuit 13 controls the write circuit 17 and the read circuit 18 based on control instructed by the command CMD and the control signal CNT.

The voltage generation circuit 14 is a circuit that generates various voltages used in the memory device 1. The voltage generation circuit 14 generates multiple voltages with different magnitudes under the control of the control circuit 13. The voltage generation circuit 14 supplies the generated voltages to the memory cell array 11, the write circuit 17, the read circuit 18, and the sense amplifier 19.

The row selection circuit 15 is a circuit that selects a row of a memory cell MC. The row selection circuit 15 receives an address signal ADD from the input/output circuit 12. The row selection circuit 15 makes a single word line WL associated with a row designated by the received address signal ADD a selected state, using a voltage received from the voltage generation circuit 14.

The column selection circuit 16 is a circuit that selects a column of a memory cell MC. The column selection circuit 16 receives an address signal ADD from the input/output circuit 12. The column selection circuit 16 makes a bit line BL associated with a column designated by the received address signal ADD a selected state, using a voltage received from the voltage generation circuit 14.

The write circuit 17 is a circuit that performs processing and control for writing data into the memory cells MC. The write circuit 17 receives data to be written from the input/output circuit 12. The write circuit 17 supplies, based on the control and data of the control circuit 13, the voltage received from the voltage generation circuit 14 to the column selection circuit 16.

The read circuit 18 is a circuit that performs processing and control for reading data from the memory cells MC. The read circuit 18 supplies voltages received from the voltage generation circuit 14 to the column selection circuit 16 based on control of the control circuit 13. The read circuit 18 supplies a plurality of control signals for data read to the sense amplifier 19.

The sense amplifier 19 is a circuit for determining what data is stored in the memory cell MC. The sense amplifier 19 includes a plurality of sense amplifier circuits SAC (not illustrated). The sense amplifier 19 receives a plurality of voltages from the voltage generation circuit 14, and operates using the received voltages. During data read, the sense amplifier 19 amplifies a potential of a bit line BL to determine data stored in the memory cell MC of a data read target. The determined data is supplied to the input/output circuit 12.

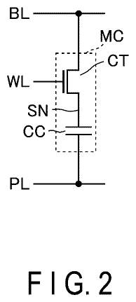

FIG. 2 illustrates components and coupling of the components of the memory cell of the memory device according to the first embodiment. Hereinafter, one of a source and a drain of a transistor may be referred to as one end of the transistor, and the other of the source and the drain may be referred to as the other end of the transistor.

As illustrated in FIG. 2, each memory cell MC includes a cell capacitor CC and an n-type metal-oxide-semiconductor field-effect transistor (MOSFET) CT. The cell capacitor CC is coupled to, at one end, a plate line PL, and is coupled to, at another end, one end of the transistor CT. The cell capacitor CC stores data using a charge stored in a node coupled to the transistor CT. A node of the cell capacitor CC that is coupled to the transistor CT may be hereinafter referred to as a “storage node SN.”

Whether or not the storage node SN stores a charge is associated with a state in which the memory cell MC stores “1” data, or a state in which “0” data is stored. Hereinafter, as an example, the state in which the storage node SN is relatively positively charged will be treated as a state in which the memory cell MC stores “1” data, and the state in which the storage node SN is not relatively positively charged will be treated as a state in which the memory cell MC stores “0” data.

The transistor CT is coupled to, at the other end, a single bit line BL, and is coupled to, at its gate, a single word line WL.

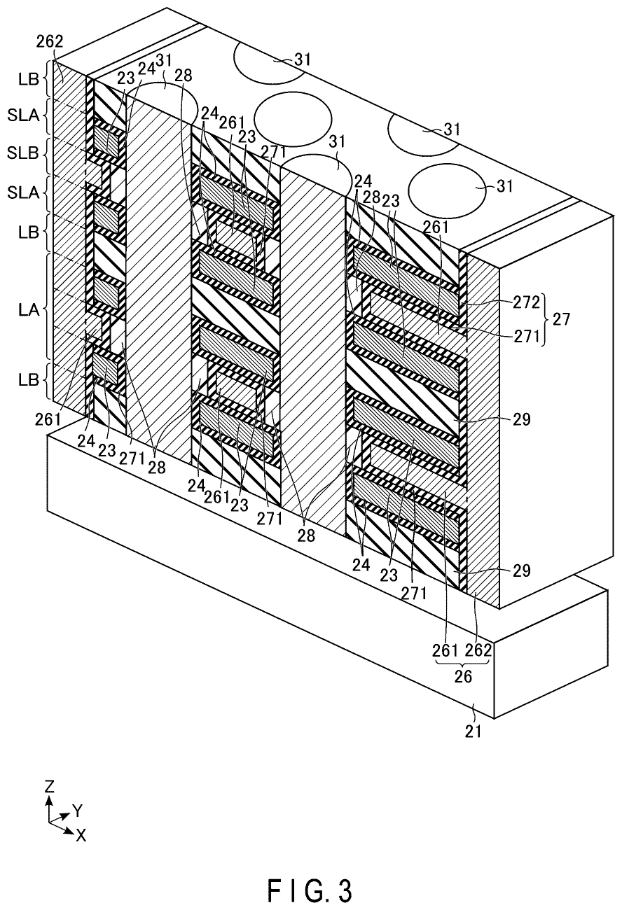

FIG. 3 is a perspective view of a structure of part of the memory device of the first embodiment. As illustrated in FIG. 3, the memory device 1 includes a substrate 21, layers LA, layers LB, sublayers SLA, a sublayer SLB, conductors 23, insulators 24, conductors 26, insulators 27, semiconductors 28, insulators 29 and conductors 31.

The layers LA and LB are located farther in the Z direction than the substrate 21. The layers LA and LB expand along the xy plane. The layers LA and LB are arranged alternately in the Z direction. Each of the layers LA includes two sublayers SLA and one sublayer SLB. One of the two sublayers SLA is located farther in the Z direction than the sublayer SLB, and the other sublayer SLA is located farther in the-Z direction than the sublayer SLB.

Each sublayer SLA includes one conductor 23 and a plurality of insulators 24. The conductor 23 expands along the xy plane over the sublayer SLA. FIG. 3 illustrates portions of the conductor 23, which are connected to each other in an unillustrated area. Two conductors 23 of respective two sublayers SLA in each layer LA are connected to each other in an unillustrated area. A plurality of conductors 23 in different layers LA are not coupled to each other. In one example, the conductor 23 includes or substantially consists of tungsten (W), molybdenum (Mo) or ruthenium (Ru). The wording “substantially consists of” and its similar wording means that a component that “substantially consists of something” may include unintended impurities. In one example, the conductor 23 includes tungsten, molybdenum or ruthenium and titanium nitride (TiN) on a surface of tungsten, molybdenum or ruthenium. In one example, the conductor 23 includes a dopant and thus includes conductive polysilicon. In one example, the conductor 23 includes a dopant and thus includes conductive polysilicon and germanium (Ge) on a surface of the polysilicon. The conductor 23 functions as at least part of one word line WL.

Each of some of the insulators 24 covers a surface of one portion of the conductor 23, that is, a side surface thereof in the Z direction, a side surface thereof in the -Z direction, a side surface thereof in the X direction, and a side surface thereof in the-X direction. A surface of the portion of the conductor 23 facing a second portion 272, which will be described later, (that is, a side surface thereof in the X direction) is not covered with the insulator 24. The insulator 24 functions as a gate insulator of a transistor CT. In one example, the insulator 24 includes or substantially consists of silicon oxide, silicon nitride, hafnium oxide or hafnium zirconium (Zr) oxide.

Each sublayer SLB includes a first portion 261, a plurality of first portions 271 and a plurality of semiconductors 28. The first portion 261 is part of the conductor 26. The first portion 261 expands along the xy plane over the sublayer SLB. FIG. 3 illustrates portions of the first conductor 261, which are connected to each other in an unillustrated area. In one example, the conductor 26 includes or substantially consists of tungsten, molybdenum or ruthenium. In one example, the conductor 26 includes tungsten, molybdenum or ruthenium and titanium nitride on a surface of the tungsten, molybdenum or ruthenium. In one example, the conductor 26 includes a dopant and thus includes conductive polysilicon. In one example, the conductor 26 includes a dopant and thus includes conductive polysilicon and germanium on a surface of the polysilicon. The conductor 26 functions as at least part of the plate line PL.

The first portion 271 is part of the insulator 27. Each first portion 271 covers a surface of one first portion 261, that is, a side surface thereof in the Z direction, a side surface thereof in the −Z direction, a side surface thereof in the X direction and a side surface thereof in the −X direction. In one example, the insulator 27 includes or consists substantially of stacked zirconium oxide, aluminum (Al) oxide, zirconium oxide (ZAZ), hafnium oxide or hafnium zirconium oxide. Each first portion 271 functions as an insulator of one cell capacitor CC.

Each semiconductor 28 covers a side surface of one conductor 31, which will be described later. In one example, the semiconductor 28 includes or substantially consists of silicon. In one example, the semiconductor 28 includes or substantially consists of an oxide semiconductor. Examples of the oxide semiconductor include an oxide including one or more elements of indium (In), gallium (Ga), zinc (Zn), tin (Sn), titanium (Ti), tungsten and molybdenum. More specific examples of the oxide semiconductor include In-O, Ga-O, Zn-O, Sn-O, Indium Tin Oxide (ITO), In-Ga-Zn-O, Ti-O, W-O and Mo-O. Each semiconductor 28 is in contact with one insulator 24 on its Z-direction-side surface (top surface) and is in contact with another insulator 24 on its −Z-direction-side surface (bottom surface). Each semiconductor 28 functions as a region in which a channel of one transistor CT is formed.

The layer LB includes an insulator 29. The insulator 29 expands along the xy plane over the layer LB. FIG. 3 illustrates portions of the insulator 29, which are connected to each other in an unillustrated area. In one example, the insulator 29 includes or substantially consists of silicon oxide or silicon nitride.

Each conductor 31 has a shape of a column and extends in the Z direction. The conductor 31 penetrates the layers LA and LB. In one example, the conductor 31 includes or substantially consists of tungsten, molybdenum or ruthenium. In one example, the conductor 31 includes tungsten, molybdenum or ruthenium and titanium nitride on a surface of the tungsten, molybdenum or ruthenium. In one example, the conductor 31 includes a dopant and thus includes conductive polysilicon. In one example, the conductor 31 includes polysilicon which includes a dopant and thus has a conductivity and germanium on a surface of the polysilicon. The conductor 31 functions as part of one bit line BL.

Each second portion 262 of the conductor 26 expands along the yz plane. The second portion 262 is coupled to the first portion 261. The first and second portions 261 and 262 are formed integrally as one component.

Each second portion 272 of the insulator 27 covers a side surface of the second portion 262 (a side surface thereof in the X direction) and expands along the yz plane. The second portion 272 is connected to some of the first portions 271. These first and second portions 271 and 272 are formed integrally as on component. The second portion 272 covers a surface of a portion of the conductor 23 that faces the second portion 262 (that is, a side surface thereof in the X direction).

One semiconductor 28, an insulator 24 that is in contact with that semiconductor 28, and a portion of the conductor 23 that faces that semiconductor 28 through the insulator 24 function as one transistor CT.

One semiconductor 28, a first portion 271 that is in contact with that semiconductor 28, and a portion of the conductor 26 that faces that semiconductor 28 through that first portion 271 function as one cell capacitor CC.

FIG. 3 illustrates an example of two layers LA, but three or more layers LA may be provided.

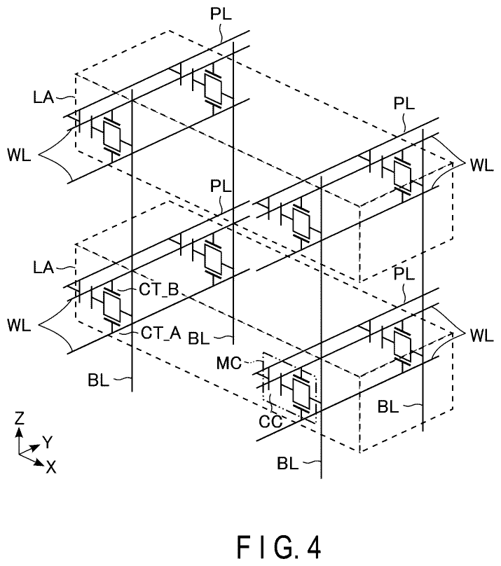

FIG. 4 illustrates components and coupling of the components of part of the memory device of the first embodiment. FIG. 4 is a circuit diagram of the structure illustrated in FIG. 3, in which the positions of the components (elements in the circuit) correspond to those of the components of the structure illustrated in FIG. 3.

Based on the structure described above with reference to FIG. 3, each memory cell MC includes two transistors CT_A and CT_B coupled in parallel as illustrated in FIG. 4. The gates of the transistors CT_A and CT_B are coupled to each other. In each layer LA, a plurality of memory cells MC are arranged in the X and Y directions.

The bit line BL extends in the Z direction and is coupled to a plurality of transistors CT_A and CT_B in different layers LA.

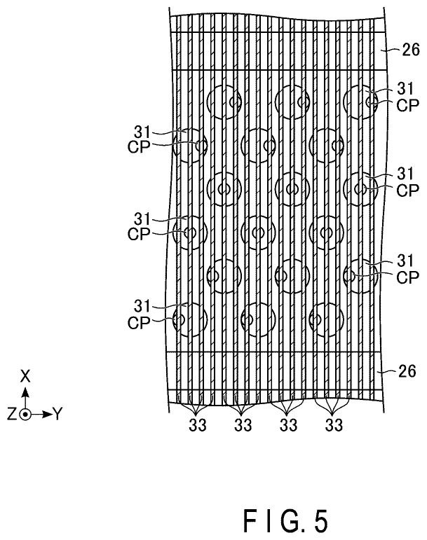

FIG. 5 illustrates a layout of components of part of the memory device of the first embodiment. FIG. 5 illustrates an area located farther in the Z direction than the structure illustrated in FIG. 3 along the xy plane.

As illustrated in FIG. 5, some conductors 31 are arranged in the X direction to form a row. FIG. 5 illustrates an example in which each row includes three conductors 31. Each row may include four or more conductors 31. The rows of conductors 31 are arranged in the Y direction. The locations (coordinates) of two adjacent conductors 31 in the Y direction on the x axis are shifted from each other. That is, if a first row of conductors 31 and a second row of conductors 31 are adjacent to each other, the conductors 31 are arranged in the following manner. Each of the conductors 31 in the first row is aligned with none of the conductors 31 in the second row in the X direction. The x-axis coordinates of each conductor 31 in the first row have coordinates between the respective x-axis coordinates of two adjacent conductors 31 in the second row. In one example, the x-axis coordinates of each conductor 31 in the first row have the x-axis coordinates at the center of the respective x-axis coordinates of two adjacent conductors 31 in the second row.

The memory device 1 further includes a plurality of conductors 33. The conductors 33 extend in the X direction and are aligned in the Y direction. Each of the conductors 33 overlaps at least one conductor 31. In the example of FIG. 5, three aligned conductors 33 overlap one row of conductors 31. Each conductor 33 is coupled to one conductor 31 via a contact CP. The contact CP is in contact with one conductor 31 and one conductor 33. Each conductor 33 functions as part of one bit line BL.

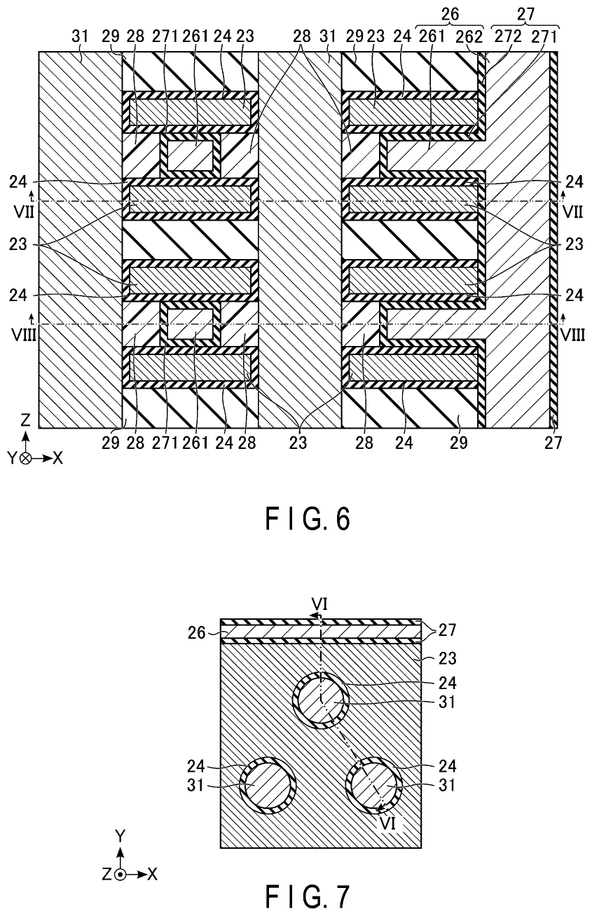

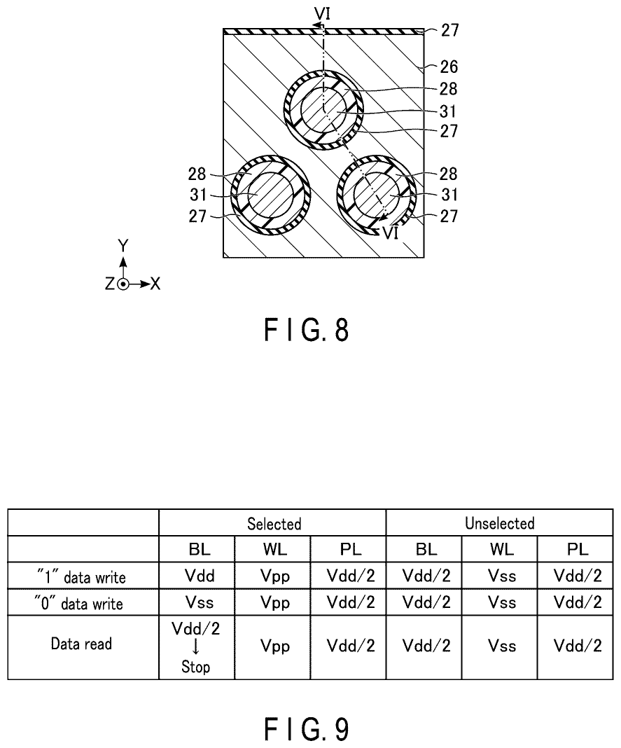

FIGS. 6, 7 and 8 each illustrate a cross-sectional structure of part of the memory device of the first embodiment. FIG. 7 illustrates a structure of the sublayer SLA along the xy plane and along the line VII-VII of FIG. 6. FIG. 8 illustrates a structure of the sublayer SLB along the xy plane and along the VIII-VIII line of FIG. 6. FIG. 6 illustrates a structure along line VI-VI in FIGS. 7 and 8.

As illustrated in FIGS. 6, 7 and 8, each insulator 24 surrounds one conductor 31 along the xy plane. Each insulator 24 is surrounded by one conductor 23.

Each semiconductor 28 surrounds one conductor 31 along the xy plane. Each semiconductor 28 is surrounded by an insulator 27 (especially, the first portion 271) along the xy plane. Each insulator 27 (especially, the first portion 271) is surrounded by the conductor 26.

### 1.2. Operation

The voltage applied to interconnect during data write and read is the same as a voltage in a generally-used DRAM, as will be described below.

FIG. 9 illustrates a voltage applied to an interconnect during an operation of the memory device of the first embodiment. As illustrated in FIG. 9, “selected” in FIG. 9 indicates that the interconnect belonging to the column of “selected” is coupled to a memory cell MC to which data is written or from which data is read, that is, “selected” indicates selected interconnect. In FIG. 9, “unselected” indicates that the interconnect belonging to the column of “unselected”column is not selected.

During “1” data write, “0” data write and data read, the unselected bit line BL, unselected word line and plate line PL receive voltage Vdd/2, ground voltage Vss and voltage Vdd/2, respectively. The ground voltage Vss is applied to the memory device 1 from outside, and is 0 V in one example. The voltage Vdd is a power supply voltage applied to the memory device 1 from outside, and is higher than the ground voltage Vss.

During the “1” data write, the selected bit line BL, selected word line WL and plate line PL receive voltages Vdd, Vpp and Vdd/2, respectively. The voltage Vpp is an internal voltage generated from the power supply voltage Vdd by the voltage generation circuit 14, and is lower than the power supply voltage Vdd in one example.

During the “0” data write, the selected bit line BL, selected word line WL and plate line PL receive the ground voltage Vss, the voltage Vpp and the voltage Vdd/2, respectively.

During the data read, the selected word line WL and plate line PL receive voltages Vpp and Vdd/2, respectively. During the data read, the selected bit line BL receives and then stops receiving the voltage Vdd/2, i.e., it is brought into an electrically floating state. During the period of stopping receiving the voltage (that is, in the electrically floating state), a potential based on data stored in a data-read target memory cell MC appears on the bit line BL. Then, the potential on the bit line BL is amplified by the sense amplifier to determine what data is stored.

### 1.3. Manufacturing Method

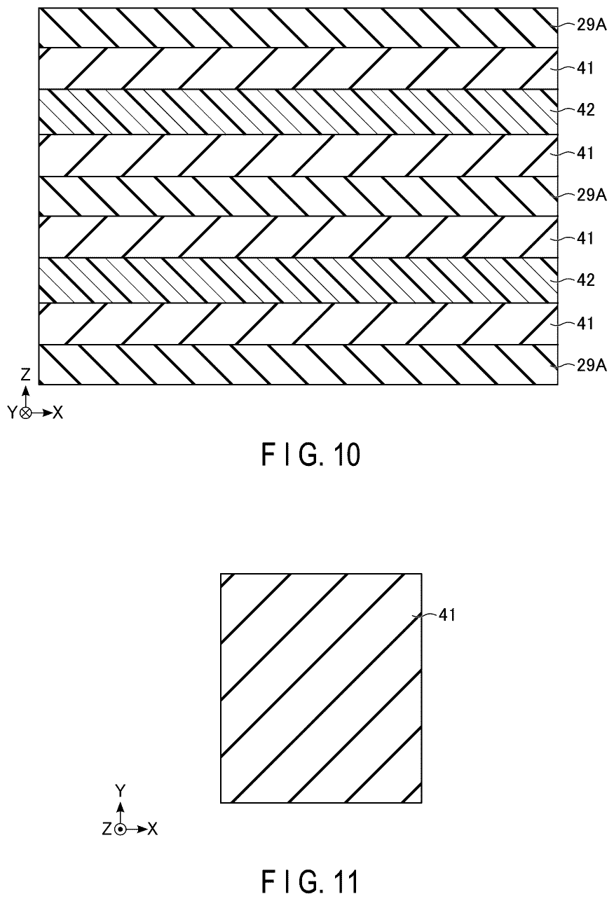

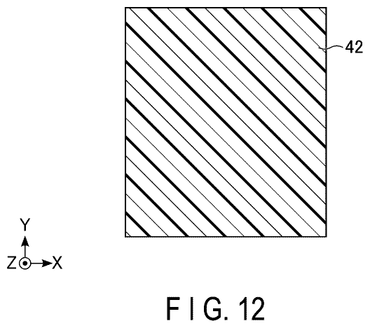

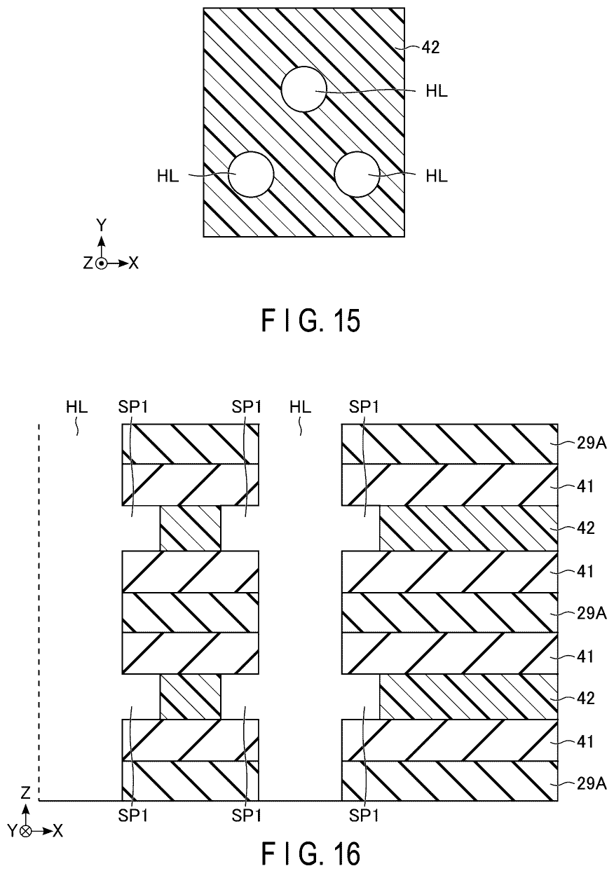

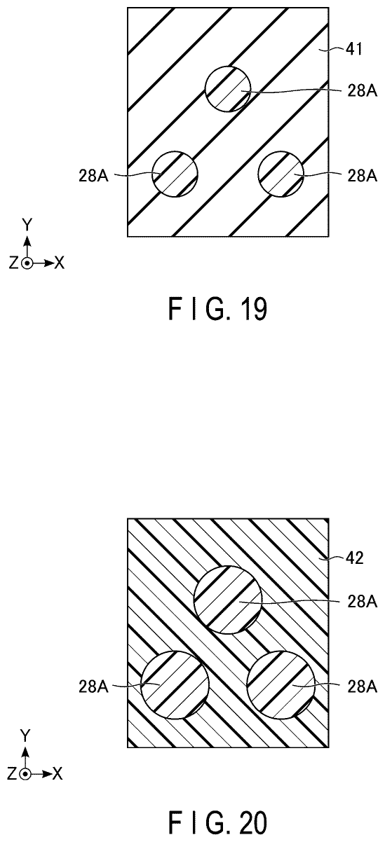

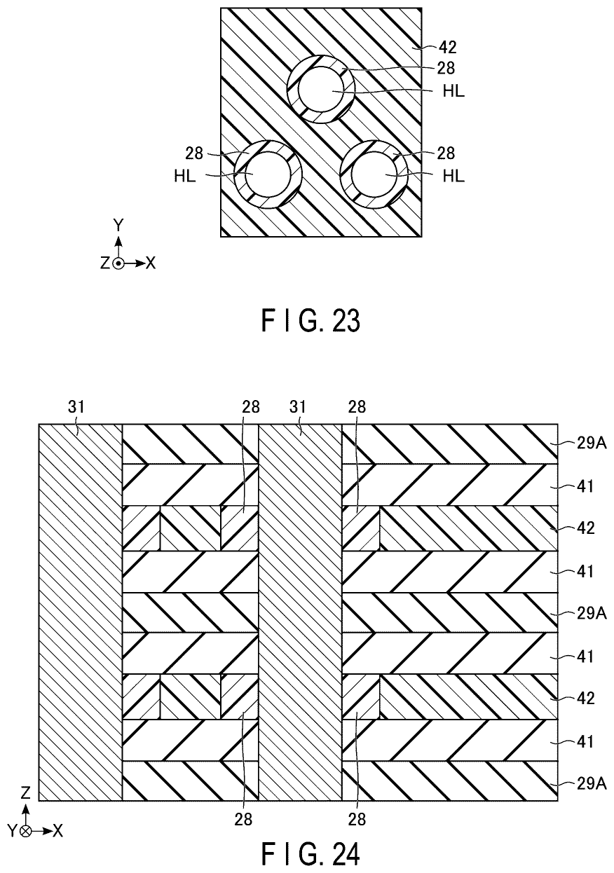

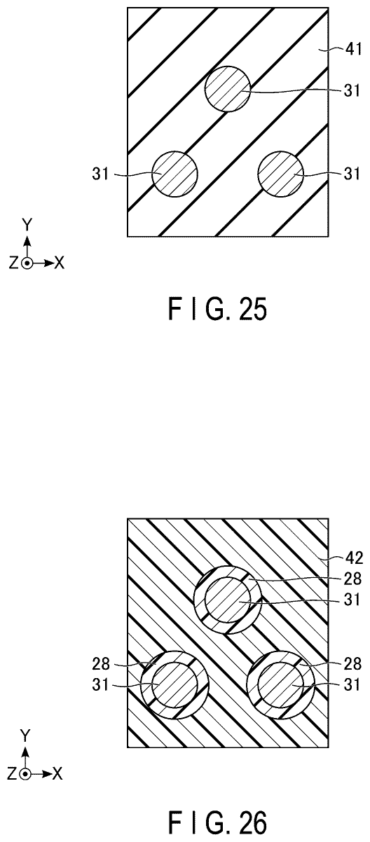

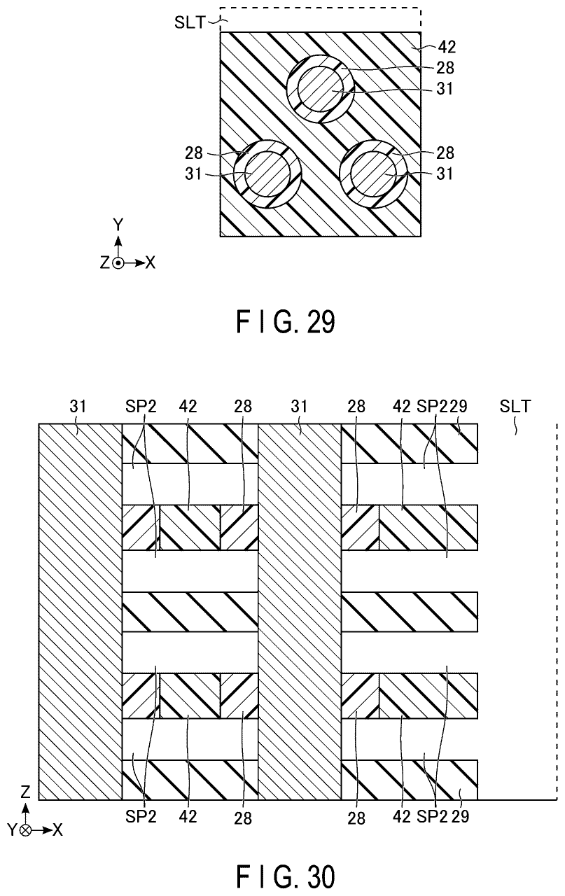

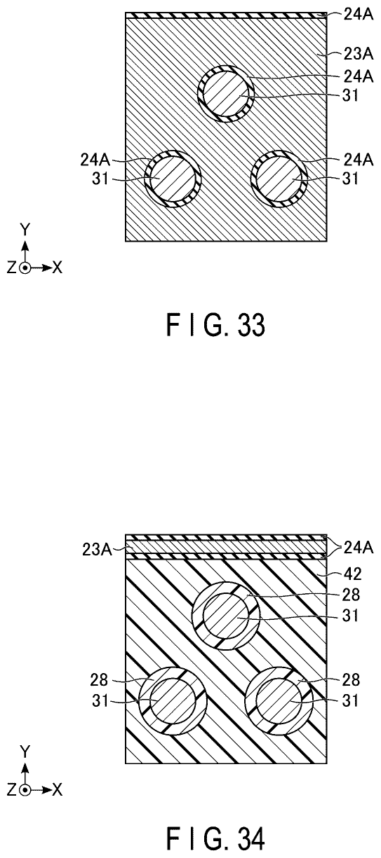

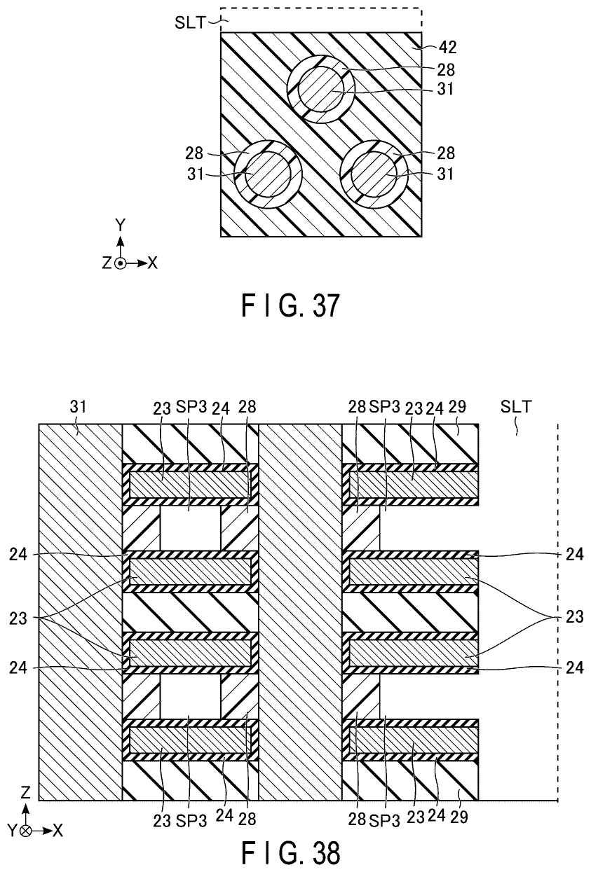

FIGS. 10 to 39 each illustrate a state during manufacturing of the memory device of the first embodiment. FIGS. 10, 13, 16, 18, 21, 24, 27, 30, 32, 35 and 38 illustrate the area illustrated in FIG. 6. FIGS. 11, 14, 19, 22, 25, 28, 31, 33 and 36 illustrate the area illustrated in FIG. 7. FIGS. 12, 15, 17, 20, 23, 26, 29, 34, 37 and 39 illustrate the area shown in FIG. 8.

As illustrated in FIGS. 10, 11 and 12, a plurality of sets of insulator 29A, sacrificial material 41, sacrificial material 42 and sacrificial material 41 are deposited. In each of the sets, the sacrificial material 41 is located on a surface (top) of the insulator 29A in the Z direction, the sacrificial material 42 is located on a top of the sacrificial material 41 and the sacrificial material 41 is located on a top of the sacrificial material 42.

The insulator 29A occupies a layer where a layer LB is to be located. The insulator 29A is an element that is to be formed into an insulator 29 in a later step. The insulator 29A includes or substantially consists of the same material as that of the insulator 29.

The sacrificial material 41 occupies a layer where a sublayer SLA is to be located. The sacrificial material 41 is made of a material having an etching rate that differs from that of the insulator 29A and the sacrificial material 42 for certain etching. The sacrificial material 41, in one example, includes or substantially consists of silicon nitride.

The sacrificial material 42 occupies a layer where a sublayer SLB is to be located. The sacrificial material 42 is made of a material having an etching rate that differs from that of the insulator 29A and the sacrificial material 41 for certain etching. In one example, the sacrificial material 42 includes or substantially consists of polysilicon.

Examples of a method of forming the insulator 29A, sacrificial material 41 and sacrificial material 42 include chemical vapor deposition (CVD).

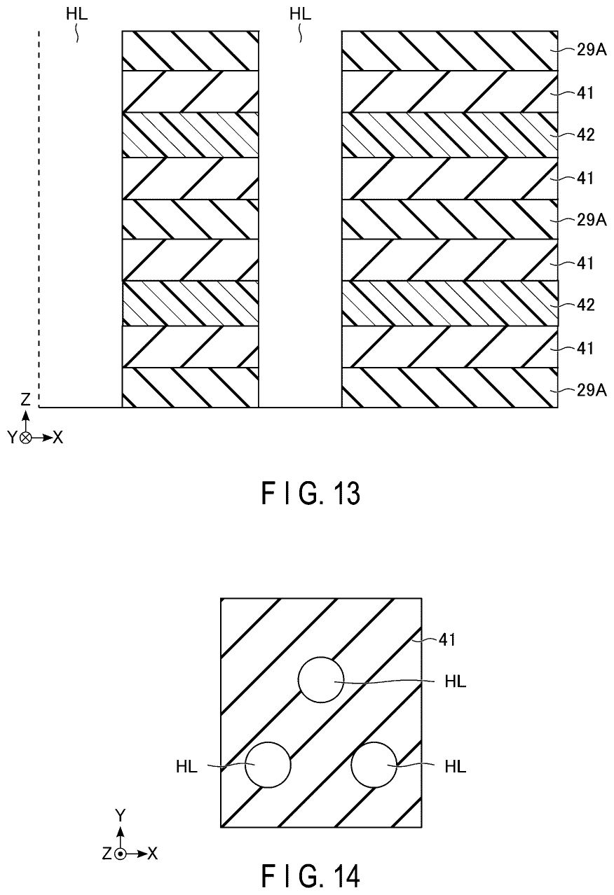

As illustrated in FIGS. 13, 14 and 15, holes HL are formed. The hole HL extends in the Z direction and penetrates the insulator 29A, sacrificial materials 41 and sacrificial material 42. The hole HL is located in an area where a conductor 31 is to be formed. The insulator 29A, sacrificial material 41 and sacrificial material 42 are exposed in the hole HL. Examples of a method of forming the hole HL include a combination of photolithography and anisotropic etching. More specifically, a mask having an opening is formed on a top of the topmost insulator 29A. The opening is located above an area where the hole HL is to be formed. Then, anisotropic etching is performed through the mask. Examples of the anisotropic etching include reactive ion etching (RIE).

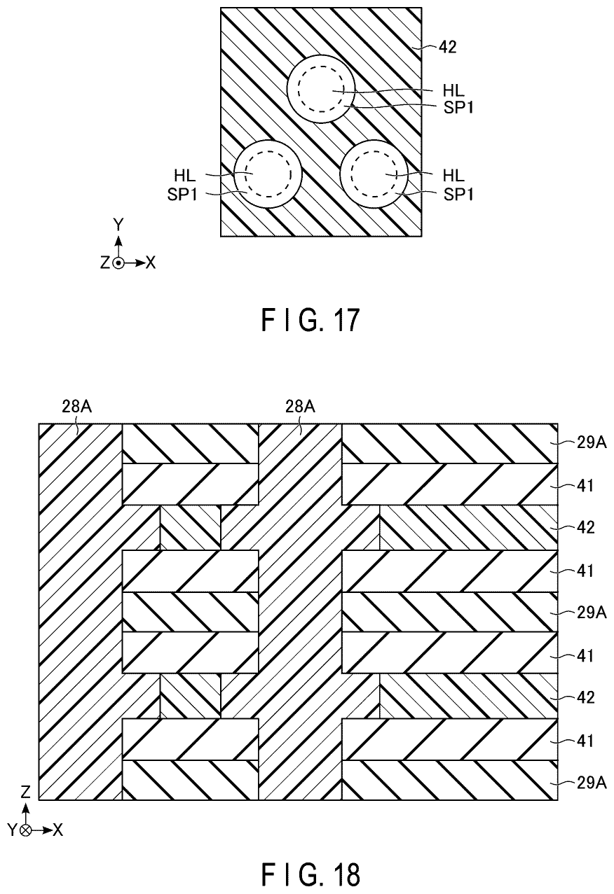

As illustrated in FIGS. 16 and 17, portion of each sacrificial material 42, including a surface thereof exposed in the hole HL is removed. Thus, a space SP1 is formed in an area where the removed portion of the sacrificial member 42 was located. The space SP1 is connected to the hole HL. The space SP1 surrounds the hole HL along the xy plane. Examples of the removing method include wet etching.

As illustrated in FIGS. 18, 19 and 20, semiconductors 28A are formed. The semiconductor 28A is an element that is formed into a semiconductor 28 by a later step. The semiconductor 28A fills the hole HL and space SP1. The semiconductor 28A is in contact with the sacrificial material 42 in the space SP1. The semiconductor 28A is made of substantially the same material as that of the semiconductor 28. Examples of a method of forming the semiconductor 28A include CVD.

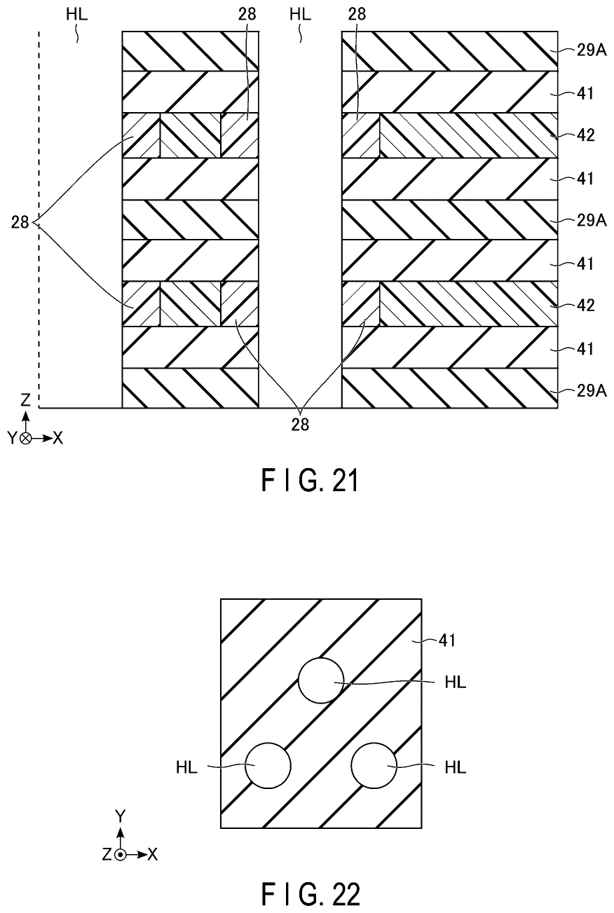

As illustrated in FIGS. 21, 22 and 23, the semiconductors 28A are partially removed. Specifically, a portion of the semiconductor 28A in the hole HL is removed. With this removal, a semiconductor 28 is formed from a portion of the semiconductor 28A other than the portion in the hole HL. With the partial removal of the portion of semiconductor 28A, a hole HL is formed again. Examples of the removing method include anisotropic etching such as RIE.

As illustrated in FIGS. 24, 25 and 26, conductors 31 are formed. The conductor 31 fills the hole HL. The conductor 31 is in contact with the semiconductor 28. Examples of the conductor forming method include CVD.

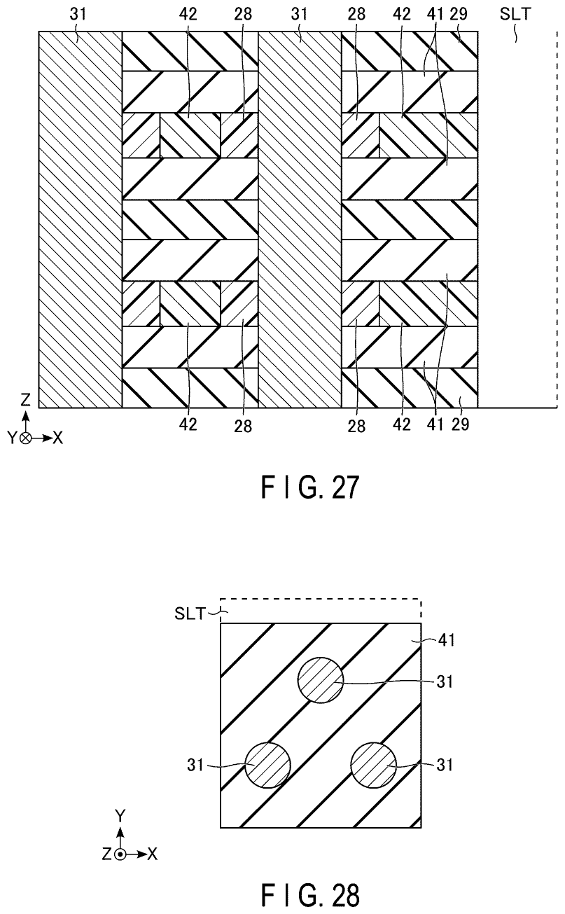

As illustrated in FIGS. 27, 28 and 29, a slit SLT is formed. The slit SLT is located in an area where the second portion 262 of the conductor 26 and the second portion 272 of the insulator 27 are to be formed. The slit SLT penetrates the insulator 29A and sacrificial material 41 and 42. The slit SLT expands along the xz plane. Examples of the slit forming method include a combination of photolithography and anisotropic etching. Examples of the anisotropic etching include RIE.

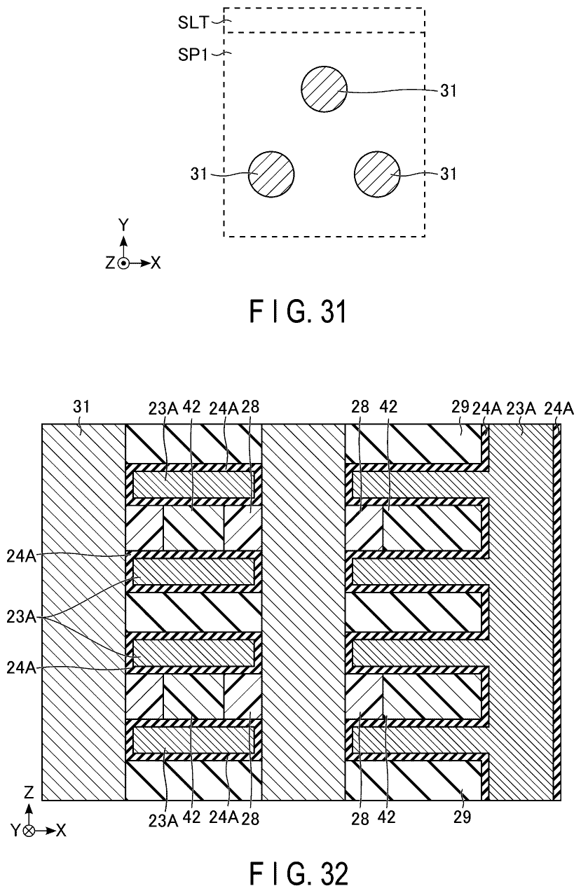

As illustrated in FIGS. 30 and 31, the sacrificial materials 41 are removed. With this removal, a space SP2 is formed in the area where the sacrificial material 41 was located. The space SP2 is connected to the slit SLT. Examples of the removing method include wet etching. The chemical of the wet etching reaches the sacrificial material 41 from the slit SLT to remove the sacrificial material 41.

As illustrated in FIGS. 32, 33 and 34, insulators 24A and conductors 23A are formed. Specifically, first, the insulator 24A is formed. The insulator 24A covers a surface of the space SP2 and a surface of an element defining the slit SLT. That is, the insulator 24A covers the surface of the insulator 29 exposed in the space SP2, a surface of the insulator 29 exposed in the slit SLT, a surface of the sacrificial material 42 exposed in the space SP2, and a surface of the sacrificial material 42 exposed in the slit SLT. The insulator 24A covers a portion of a surface of the semiconductor 28 which is exposed in the space SP2. The insulator 24A is an element that is to be formed into the insulator 24 by a later step. The insulator 24A substantially consists of the same material as that of the insulator 24. Examples of a method of forming the insulators 24A include CVD.

Then, the space SP2 and slit SLT are filled with the conductor 23A. The conductor 23A is an element that is to be formed into the conductor 23 by a later step. The conductor 23A substantially consists of the same material as that of the conductor 23. Examples of a method of forming the conductors 23A include CVD.

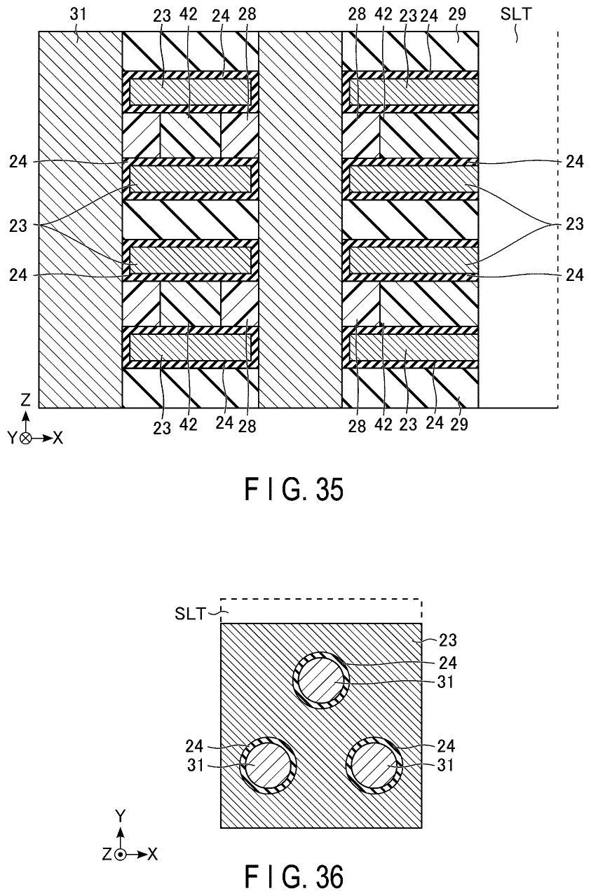

As illustrated in FIGS. 35, 36 and 37, the conductors 23A and insulators 24A are partially removed. That is, first, a portion of the conductor 23A in the slit SLT is removed. Thus, a conductor 23 is formed from the remaining portion of the conductor 23A. Examples of a method of partially removing the conductors 23A include a combination of photolithography and anisotropic etching. Examples of the anisotropic etching include RIE.

Then, a portion of the insulator 24A in the slit SLT, that is, a portion of the insulator 24A which are on surfaces of the insulator 29 and sacrificial material 42 which face the slit SLT is removed. Thus, insulator 24 is formed from the remaining portion of the insulator 24A. Examples of a method of partially removing the insulator 24A include a combination of photolithography and anisotropic etching. Examples of the anisotropic etching include RIE.

With the partial removal of the conductor 23A and insulator 24A, the slit SLT is formed again.

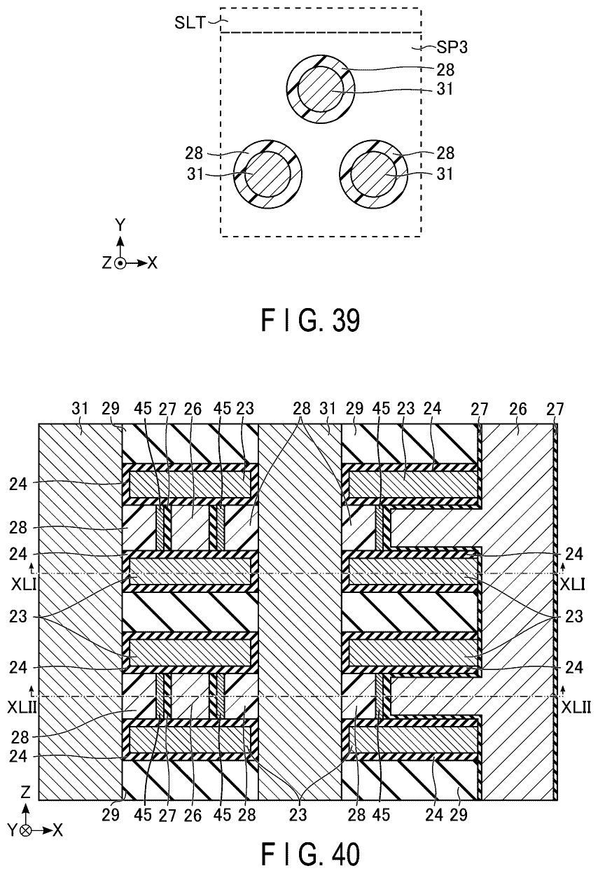

As illustrated in FIGS. 38 and 39, the sacrificial material 42 is removed. With the removal of the sacrificial material 42, a space SP3 is formed in an area where the sacrificial material 42 was located. The space SP3 is connected to the slit SLT. The space SP3 surrounds the semiconductor 28 along the xy plane. The space SP3 exposes the semiconductor 28. Examples of the removal method include wet etching. The chemical of the wet etching reaches the sacrificial material 42 from the slit SLT to remove the sacrificial material 42.

As illustrated in FIGS. 6, 7 and 8, the insulator 27 and conductor 26 are formed. That is, first, the insulator 27 that covers the surface of an element defining the slit SLT and the space SP2 is formed. That is, the insulator 27 covers a surface of the insulator 29 exposed in the slit SLT, a surface of the conductor 23 exposed in the slit SLT, a surface of the insulator 24 exposed in the slit SLT and space SP3, and portion of the semiconductor 28 exposed in the space SP3. Examples of a deposition method include CVD.

A conductor 26 is then formed on the insulator 27. The conductor 26 fills the slit SLT and space SP3 with the insulator 27 therebetween. Examples of the forming method include CVD.

### 1.4. Advantages (Advantageous Effects)

The memory device 1 of the first embodiment includes the conductor 31 which extends in the Z direction, the semiconductor 28 which surrounds the conductor 31, the insulator 27 which surrounds the semiconductor 28, the conductor 26 which surrounds the insulator 27, the insulator 24 which is located farther in the Z or −Z direction than the semiconductor 28 and which is in contact with the semiconductor 28, and the conductor 23 which is located farther in the Z or −Z direction than the semiconductor 28, is in contact with the insulator 24 and surrounds the conductor 31. The semiconductor 28, the insulator 24, and a portion of the conductor 23 which faces the semiconductor 28 via the insulator 24 can function as one transistor CT. The semiconductor 28, insulator 27 and conductor 26 can function as one cell capacitor CC. Therefore, the structure of the memory device 1 achieves a DRAM structure having a small-sized memory cell MC.

### 2. Second Embodiment

### 2.1. Configuration

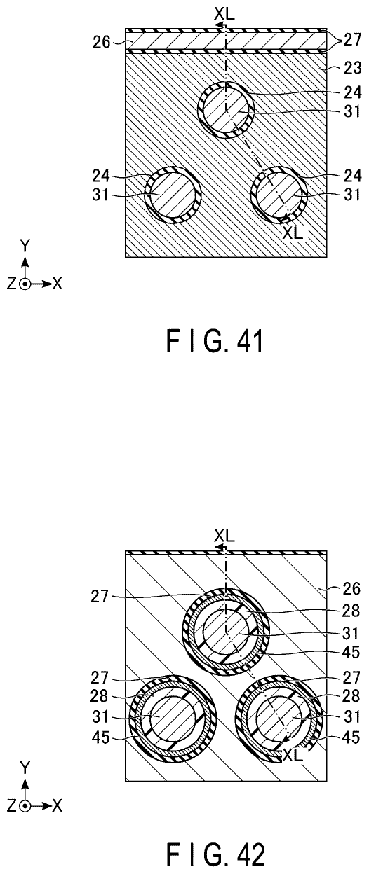

FIGS. 40, 41 and 42 each illustrate a cross-sectional structure of part of a memory device of a second embodiment. FIGS. 40, 41 and 42 respectively illustrate areas corresponding to the areas illustrated in FIGS. 6, 7 and 8 of the first embodiment. FIG. 41 illustrates a structure along line XLI-XLI of FIG. 40. FIG. 42 illustrates a structure along line XLII-XLII of FIG. 40. FIG. 40 illustrates a structure along line XL-XL of FIGS. 41 and 42.

As illustrated in FIGS. 40, 41 and 42, the memory device 1 of the second embodiment further includes a plurality of conductors 45. The conductor 45 is located in the sublayer SLB (in which the semiconductor 28 is located). The conductor 45 surrounds one semiconductor 28 along the xy plane, is in contact with one semiconductor 28, and covers the semiconductor 28. The conductor 45 is surrounded by one insulator 27 along the xy plane. In one example, the conductor 45 includes or substantially consists of ITO or titanium nitride.

### 2.2. Manufacturing Method

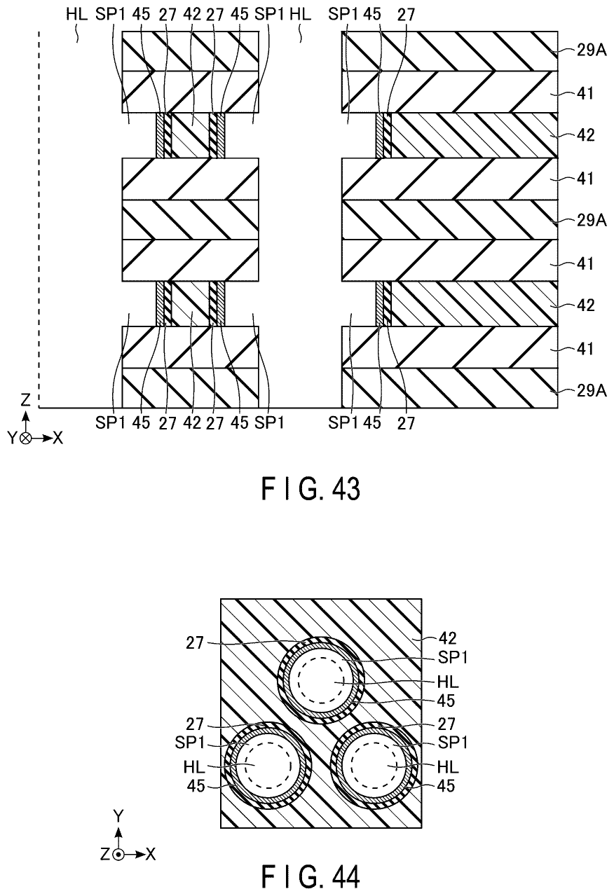

FIGS. 43 to 48 each illustrate one state during manufacturing of the memory device of the second embodiment. FIGS. 43, 45 and 47 each illustrate the area illustrated in FIG. 40. FIGS. 44, 46 and 48 each illustrate the area illustrated in FIG. 42.

First, the steps described above with reference to FIGS. 16 and 17 of the first embodiment are executed.

As illustrated in FIGS. 43 and 44, an insulator 27 and a conductor 45 are formed. The insulator 27 covers a surface of the sacrificial material 42 which is exposed in the space SP1. The conductor 45 covers a surface of the insulator 27 which is exposed in the space SP1.

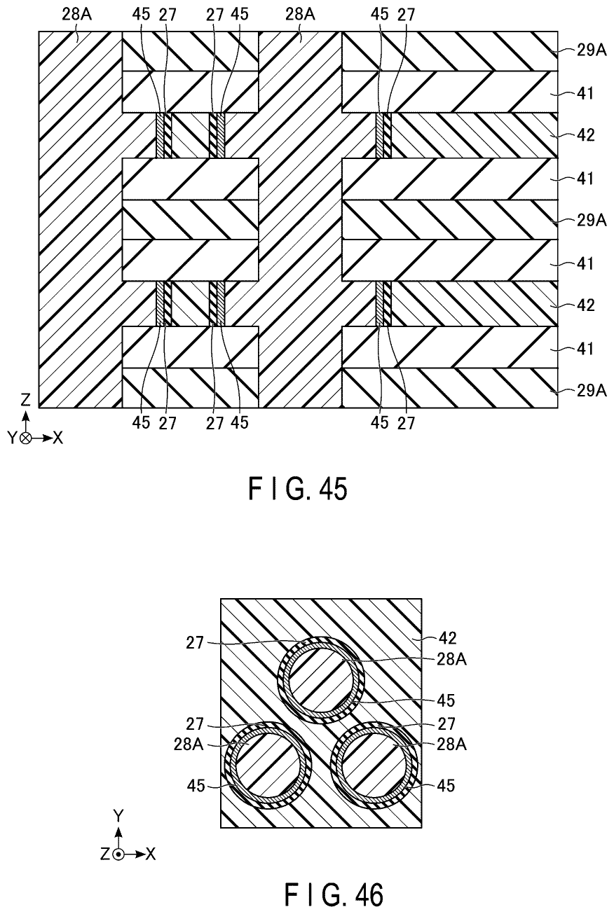

As illustrated in FIGS. 45 and 46, a semiconductor 28A is formed. The semiconductor 28A fills the hole HL and the space SP1. The semiconductor 28A is in contact with the conductor 45 in the space SP1.

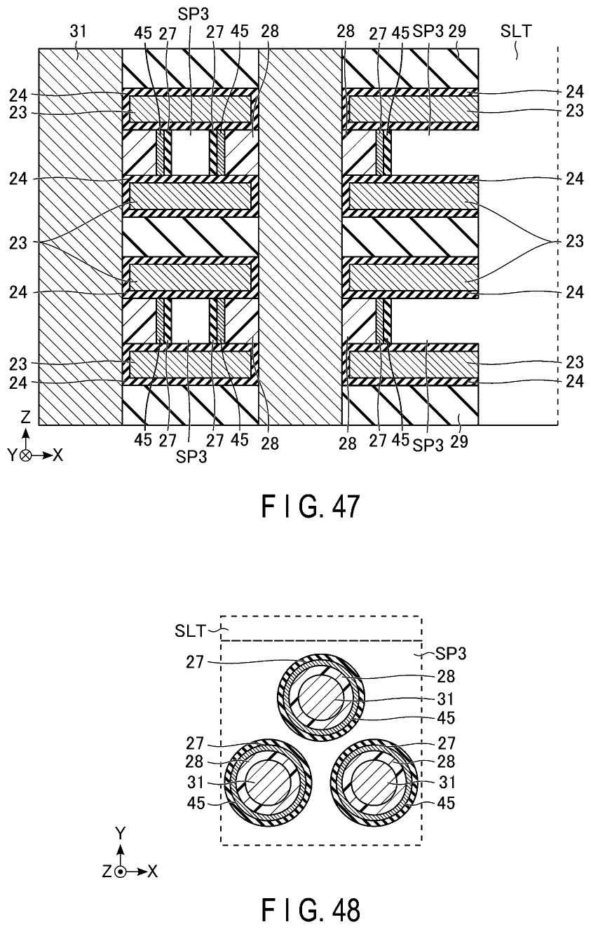

As illustrated in FIGS. 47 and 48, the conductor 31, the conductor 23, the insulator 24 and the slit SLT are formed. First, a portion of the semiconductor 28A in the hole HL is removed by the same steps as those described above with reference to FIGS. 21 to 23 of the first embodiment, thereby forming a semiconductor 28.

The conductor 31 is formed by the same steps as those described above with reference to FIGS. 24 to 26 of the first embodiment.

The slit SLT is formed by the same steps as those described above with reference to FIGS. 27 to 29 of the first embodiment.

The sacrificial material 41 is removed by the same steps as those described above with reference to FIGS. 30 and 31 of the first embodiment, thereby forming a space SP2.

The conductor 23, insulator 24 and slit SL are formed by the same steps as those described above with reference to FIGS. 32 to 34 of the first embodiment and the same steps as those described above with reference to FIGS. 35 to 37.

The sacrificial material 42 is removed by the same steps as those described above with reference to FIGS. 38 and 39 of the first embodiment, thereby forming the space SP3.

As illustrated in FIGS. 40, 41 and 42, the insulator 27 and the conductor 26 are formed by the same steps as those described above with reference to FIGS. 6, 7 and 8 of the first embodiment.

### 2.3. Advantages

Like the structure of the first embodiment, the structure of the second embodiment achieves a DRAM structure having a small-sized memory cell MC.

### 2.4. Modification

The conductors 45 may be formed using the slit SLT. That is, after the steps described above with reference to FIGS. 38 and 39 of the first embodiment, the conductor 45 is formed on a surface of the semiconductor 28 that is exposed into the space SP3 from the slit SLT. Then, the insulator 24 is formed.

### 3. Third Embodiment

### 3.1. Configuration

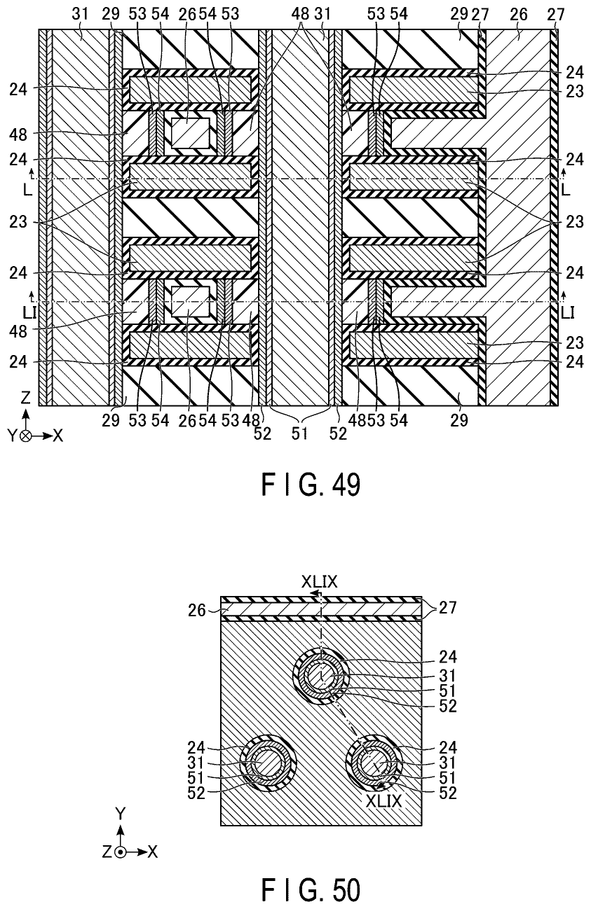

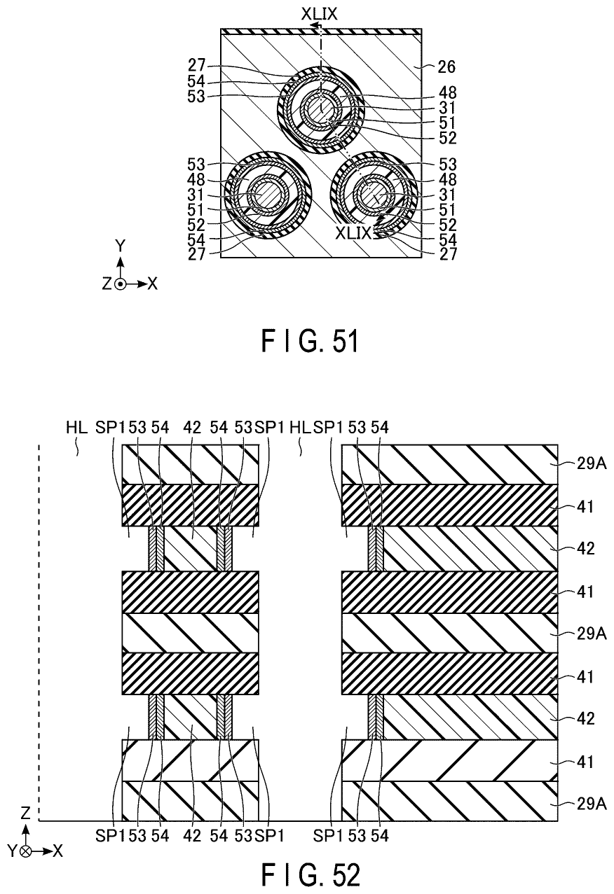

FIGS. 49, 50 and 51 each illustrate a cross-sectional structure of part of a memory device of a third embodiment. FIGS. 49, 50 and 51 respectively illustrate areas corresponding to the areas illustrated in FIGS. 6, 7 and 8 of the first embodiment. FIG. 50 illustrates a structure along line L-L of FIG. 49. FIG. 51 illustrates a structure along the xy-plane of a sublayer SLB and along line LI-LI of FIG. 49. FIG. 49 illustrates a structure along line XLIX-XLIX of FIGS. 50 and 51.

As illustrated in FIGS. 49, 50 and 51, the memory device 1 of the third embodiment includes not the semiconductor 28 but an oxide semiconductor 48. The memory device 1 of the third embodiment further includes conductors 51, 52, 53 and 54.

The oxide semiconductor 48 occupies the area of the semiconductor 28 of the first embodiment. The oxide semiconductor 48 has conductivity. Examples of the oxide semiconductors 48 include an oxide containing one or more of indium, gallium, zinc, tin, titanium, tungsten and molybdenum.

The conductor 51 surrounds the conductor 31 along the xy plane, is in contact with the conductor 31 and covers the conductor 31. The conductor 51 has a cylindrical shape. Like the conductor 31, the conductor 51 extends in the Z direction and penetrates the layers LA and LB. In one example, the conductor 51 includes or substantially consists of titanium nitride.

The conductor 52 surrounds the conductor 51 along the xy plane, is in contact with the conductor 51 and covers the conductor 51. The conductor 52 has a cylindrical shape. Like the conductor 31, the conductor 52 extends in the Z direction and penetrates the layers LA and LB. In one example, the conductor 52 includes or substantially consists of ITO.

The conductor 53 is located in the sublayer SLB (in which the oxide semiconductor 48 is located). The conductor 53 surrounds one oxide semiconductor 48 along the xy plane, is in contact with one oxide semiconductor 48 and covers the conductor 48. In one example, the conductor 53 includes or substantially consists of ITO.

The conductor 54 is located in the sublayer SLB (in which the semiconductor 28 is located). Each conductor 54 surrounds one conductor 53 along the xy plane, is in contact with one conductor 53 and covers one conductor 53. The conductor 54 is surrounded by one insulator 27 along the xy plane. In one example, the conductor 54 includes or substantially consists of titanium nitride.

### 3.2. Manufacturing Method

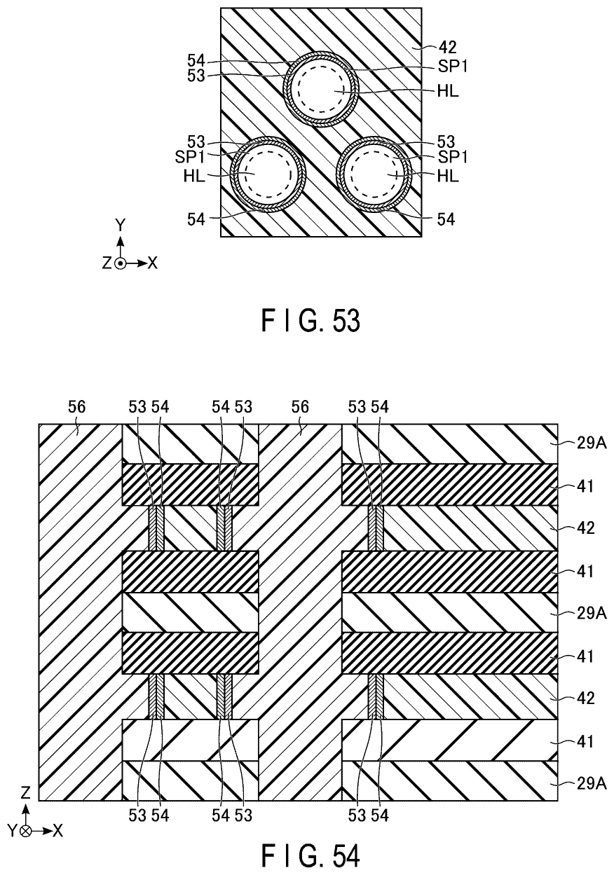

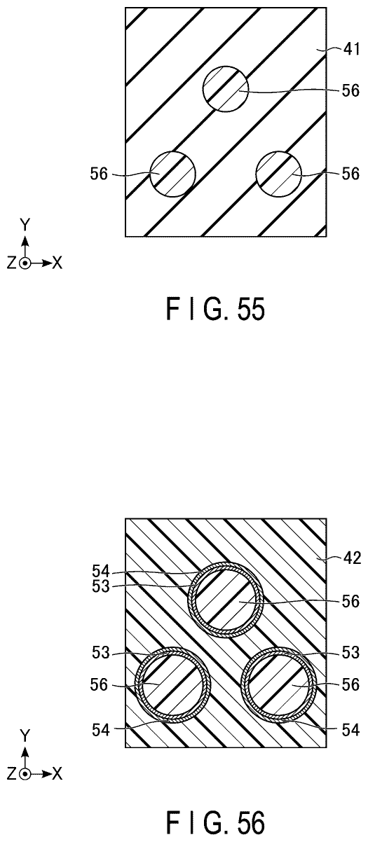

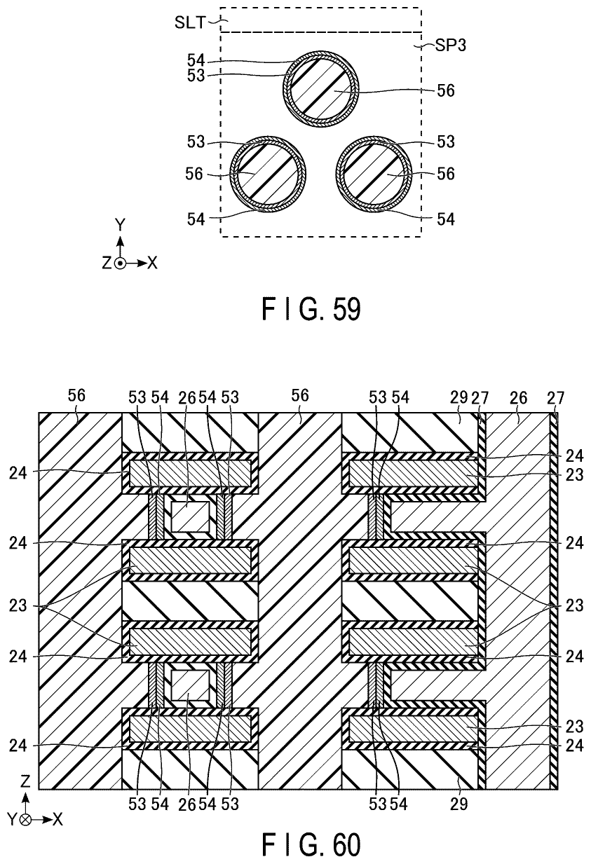

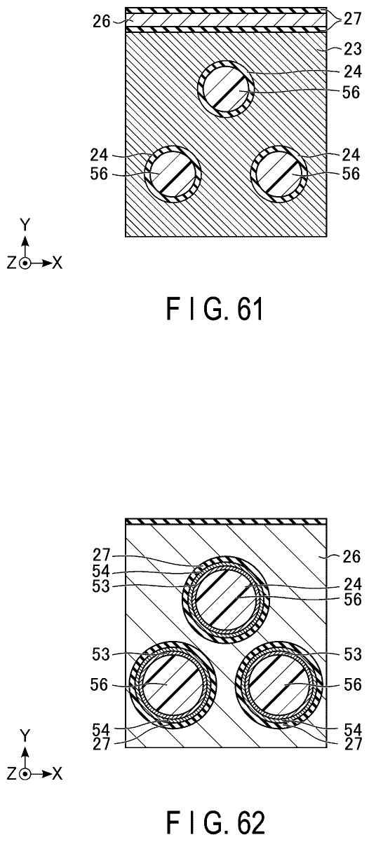

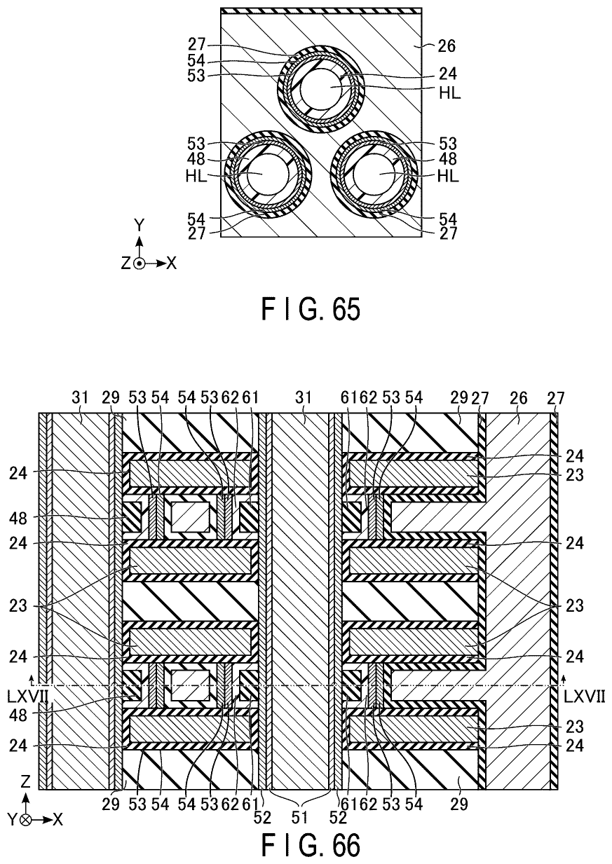

FIGS. 52 to 65 each illustrate one state during manufacturing of the memory device of the third embodiment. FIGS. 52, 54, 57, 60 and 63 each illustrate the area illustrated in FIG. 49. FIGS. 55, 58, 61 and 64 each illustrate the area illustrate in FIG. 50. FIGS. 53, 56, 59, 62 and 65 each illustrate the area illustrated in FIG. 51.

First, the steps described above with reference to FIGS. 16 and 17 of the first embodiment are executed.

As illustrated in FIGS. 52 and 53, the conductors 54 and 53 are formed. The conductor 54 covers the surface of the sacrificial material 42 that is exposed in the space SP1. The conductor 54 covers a surface of the conductor 53.

As illustrated in FIGS. 54, 55 and 56, a sacrificial material 56 is formed. The sacrificial material 56 fills the hole HL and the space SP1. In one example, the sacrificial material 56 includes or substantially consists of amorphous silicon. Examples of the forming method include CVD.

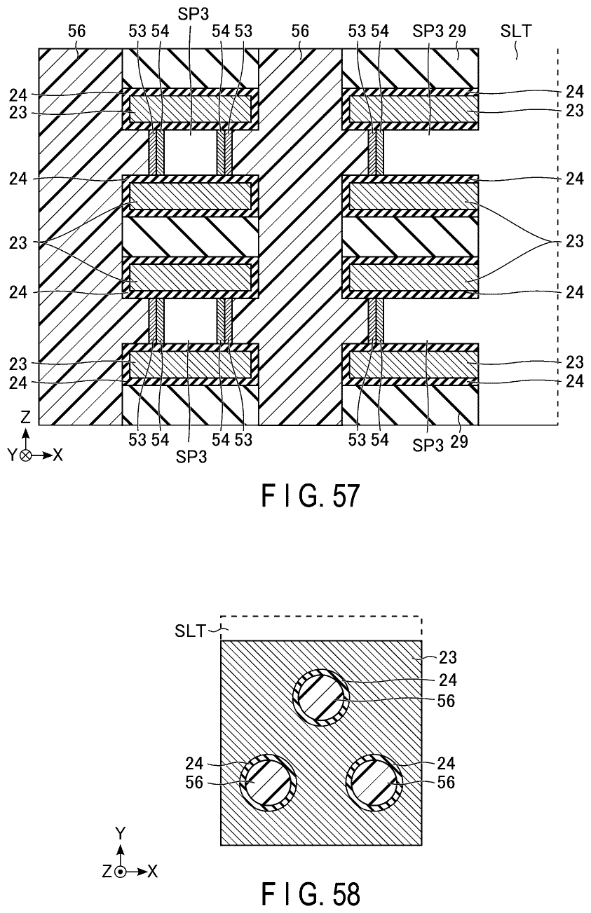

As illustrated in FIGS. 57, 58 and 59, the conductor 23, an insulator 24 and a slit SLT are formed. That is, first, the slit SLT is formed by the same steps as those described above with reference to FIGS. 27 to 29 of the first embodiment.

The sacrificial material 41 is removed by the same steps as those described above with reference to FIGS. 30 and 31 of the first embodiment, thereby forming the space SP2.

The conductor 23, insulator 24 and slit SLT are formed by the same steps as those described above with reference to FIGS. 32 to 34 of the first embodiment and the same steps as those described above with reference to FIGS. 35 to 37.

The sacrificial material 42 is removed by the same steps as those described above with reference to FIGS. 38 and 39 of the first embodiment, thereby forming the space SP3.

As illustrated in FIGS. 60, 61 and 62, the insulator 27 and the conductor 26 are formed by the same steps as those described above with reference to FIGS. 6, 7 and 8 of the first embodiment.

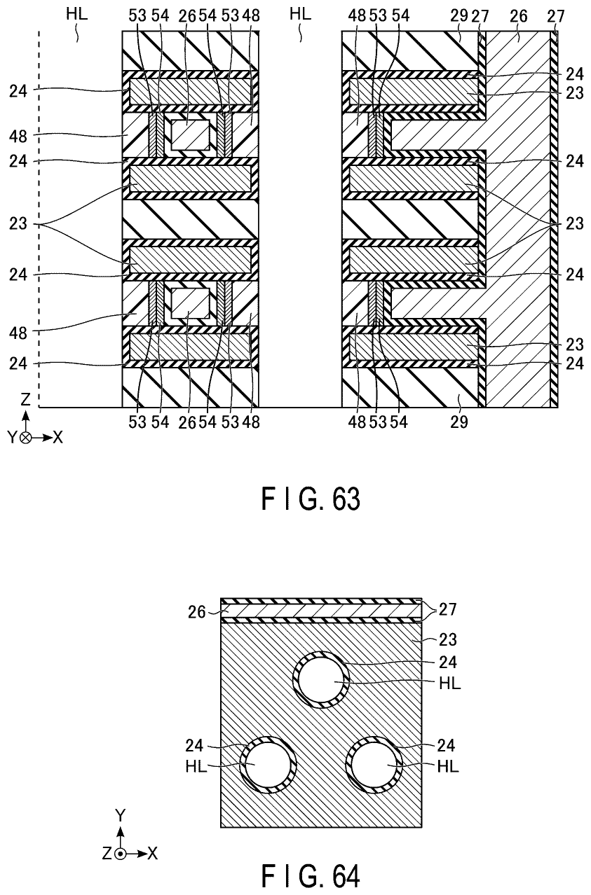

As illustrated in FIGS. 63, 64 and 65, the oxide semiconductor 48 is formed. That is, first, the sacrificial material 56 is removed and accordingly the hole HL and space SP1 are formed again. Examples of the removing method include wet etching.

An oxide semiconductor 48A is formed by the same steps as those described above with reference to FIGS. 18, 19 and 20 of the first embodiment. The oxide semiconductor 48A fills the hole HL and space SP1. Examples of the forming method include CVD.

The oxide semiconductor 48A is partially removed by the same steps as those described above with reference to FIGS. 21, 22 and 23 of the first embodiment. Thus, the oxide semiconductor 48 is formed from the remaining portion of the oxide semiconductor 48A and accordingly the hole HL is formed again. The oxide semiconductor 48 is exposed in the hole HL.

As illustrated in FIGS. 49, 50 and 51, conductors 52, 51 and 31 are formed. That is, first, the conductor 52 is formed on a surface of an element defining the holes HL, that is, the surface of the insulator 29 exposed in the hole HL, and the surface of the insulator 27 exposed in the hole HL. Examples of the forming method include CVD.

The conductor 51 is formed on the surface of the conductor 52. Examples of the forming method include CVD.

The conductor 31 is formed on the surface of the conductor 51. The conductor 31 fills an area of the hole HL where neither of the conductors 51 and 52 is located.

### 3.3. Advantages

Like the structure of the first embodiment, the structure of the third embodiment realizes a DRAM structure having a small-sized memory cell MC.

### 3.4. Modification

The memory device 1 may not include one or more of the conductors 51, 52, 53 and 54. In addition, the third embodiment may be combined with the first embodiment. That is, the memory device 1 includes the semiconductor 28 instead of the oxide semiconductor 48 and includes one or more of the conductors 51, 52, 53 and 54.

### 4. Fourth Embodiment

A fourth embodiment may be combined with the first, second or third embodiment. The following description relates to an example in which the fourth embodiment is based on the third embodiment.

### 4.1. Configuration

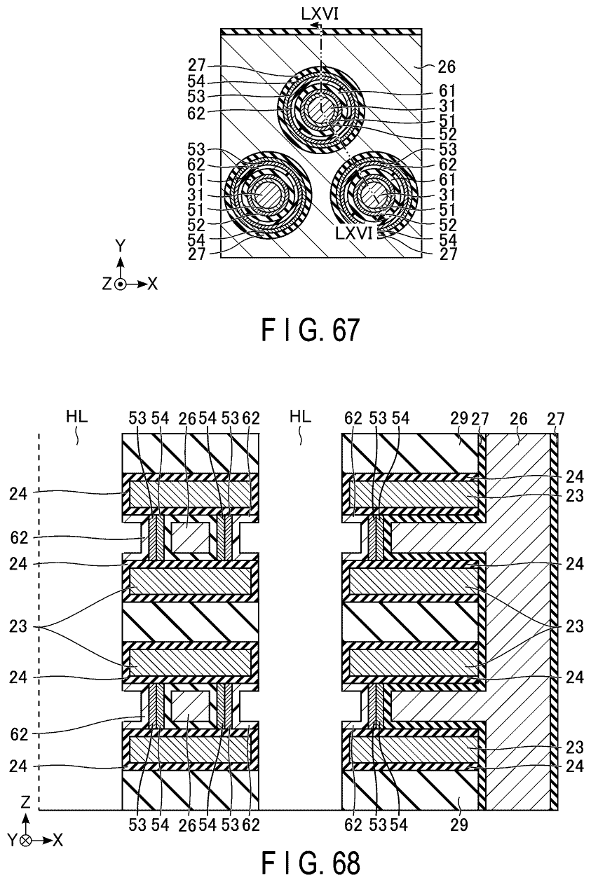

FIGS. 66 and 67 each illustrate a cross-sectional structure of part of a memory device of the fourth embodiment. FIGS. 66 and 67 respectively illustrate areas corresponding to the areas illustrated in FIGS. 6 and 8 of the first embodiment. FIG. 67 illustrates a structure along line LXVII-LXVII of FIG. 66. FIG. 66 illustrates a structure along line LXVI-LXVI of FIG. 67. The structure of a layer in which the conductor 23 is located is the same as that in FIG. 50 of the third embodiment.

As illustrated in FIGS. 66 and 67, the memory device 1 of the fourth embodiment includes not the semiconductor 28, but an insulator 61 and a semiconductor 62. A set of the insulator 61 and semiconductor 62 occupies the location of the semiconductor 28. The insulator 61 is in contact with the conductor 52. In one example, the insulator 61 includes or substantially consists of silicon oxide.

The semiconductor 62 covers a portion of a surface of the insulator 61 other than portion in contact with the conductor 52. That is, the semiconductor 62 is located between the insulators 61 and 27 and between the insulator 61 and the conductor 53, and is in contact with the insulator 27 and the conductor 53. The semiconductor 62 includes or substantially consists of the same material as that of the semiconductor 28.

### 4.2. Manufacturing Method

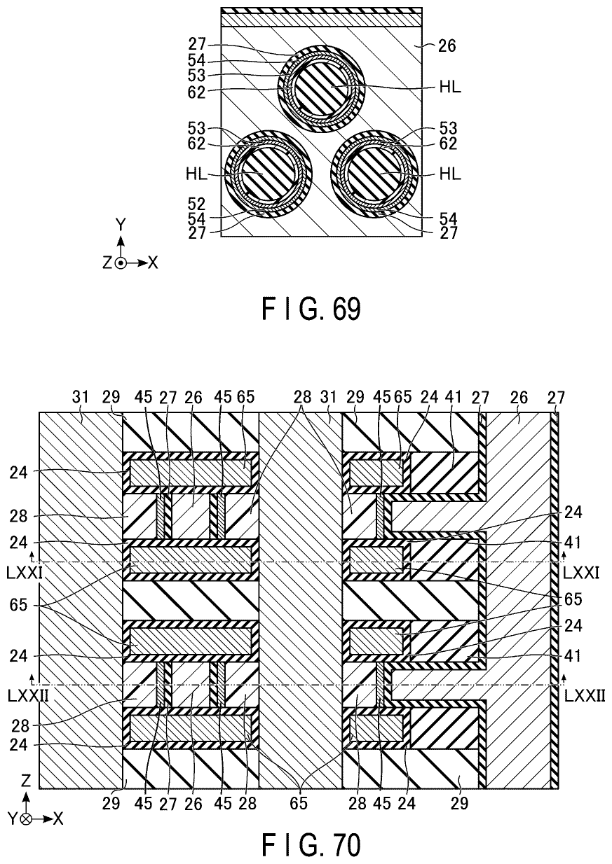

FIGS. 68 and 69 each illustrate a state during manufacturing of the memory device of the fourth embodiment. FIG. 68 illustrates the area illustrated in FIG. 66. FIG. 69 illustrates the area illustrate in FIG. 67.

First, the steps described above with reference to FIGS. 60, 61 and 62 of the fourth embodiment are executed.

As illustrated in FIGS. 68 and 69, the sacrificial material 56 is removed by the same steps as those described above with reference to FIGS. 63, 64 and 65 of the fourth embodiment. Then, a semiconductor 62A is formed in the hole HL and the space SP1. The semiconductor 62A covers the surface of the insulator 29 exposed in the hole HL, the surface of the insulator 27 exposed into the hole HL and space SP1, and a surface of the conductor 53 in the space SP1. Examples of the forming method include CVD.

Then, a portion of the semiconductor 62A which is on a portion of a suface of the insulator 29 which is exposed in the hole HL and on a portion of a surface of the insulator 27 which is exposed in the hole HL is removed. Thus, the semiconductor 62 is formed from the remaining portion.

Then, the insulator 61 is deposited on the semiconductor 62. The subsequent steps are the same as those described above with reference to FIGS. 63, 64 and 65 of the fourth embodiment.

### 4.3. Advantages

Like the structure of the first embodiment, the structure of the fourth embodiment realizes a DRAM structure having a small-sized memory cell MC. In addition, according to the fourth embodiment, a volume of channels of the transistor CT is small due to the presence of the insulator 61. Therefore, the transistor CT is easy to cut off.

### 5. Fifth Embodiment

A fifth embodiment may be combined with the first, second, third or fourth embodiment. The following description relates to an example in which the fifth embodiment is based on the second embodiment.

### 5.1. Configuration

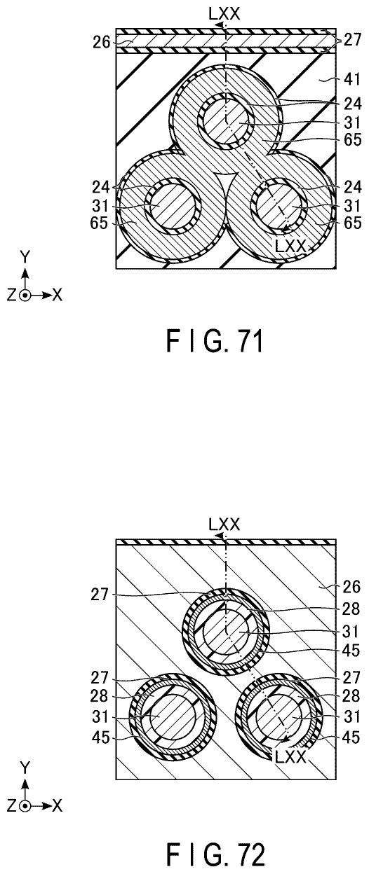

FIGS. 70, 71 and 72 each illustrate a cross-sectional structure of part of a memory device according to the fifth embodiment. FIGS. 70, 71 and 72 respectively illustrate areas corresponding to the areas illustrated in FIGS. 6, 7 and 8 of the first embodiment. FIG. 71 illustrates a structure along line LXXI-LXXI of FIG. 70. FIG. 72 illustrates a structure along line LXXII-LXXII of FIG. 70. FIG. 70 illustrate a structure along line LXX-LXX of FIGS. 71 and 72.

As illustrated in FIGS. 70, 71 and 72, the memory device 1 of the fifth embodiment includes not the conductors 23 but conductors 65.

Each conductor 65 is located in the sublayer SLA. Each conductor 65 surrounds one conductor 31 along the xy plane, is in contact with the conductor 31 and covers the conductor 31. A surface of each conductor 65 is covered with the insulator 24. Each conductor 65 faces one conductor 31 through the insulator 24. Depending on the size and arrangement of the conductors 31, conductors 65 respectively surrounding adjacent conductors 31 are connected to each other, and the insulators 24 surrounding adjacent conductors 31 are connected to each other. FIGS. 70, 71 and 72 each illustrate an example of such connecting. If adjacent conductors 31 are located away from each other, the conductors 65 are separate and so are the insulators 24.

A sacrificial material 41 is provided in an area of the sublayer SLA where the conductor 31, conductor 65, insulator 24, conductor 26 or the insulator 27 is not located.

### 5.2. Manufacturing Method

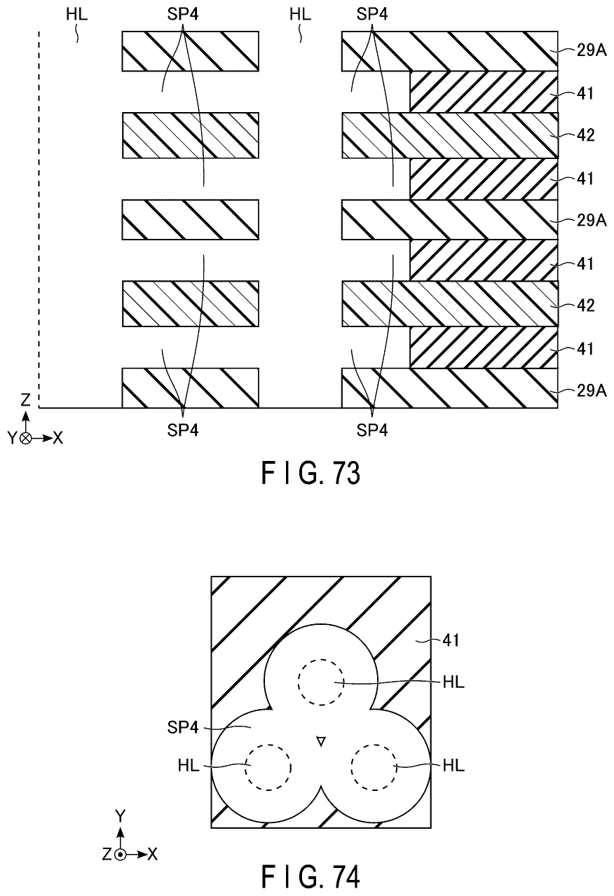

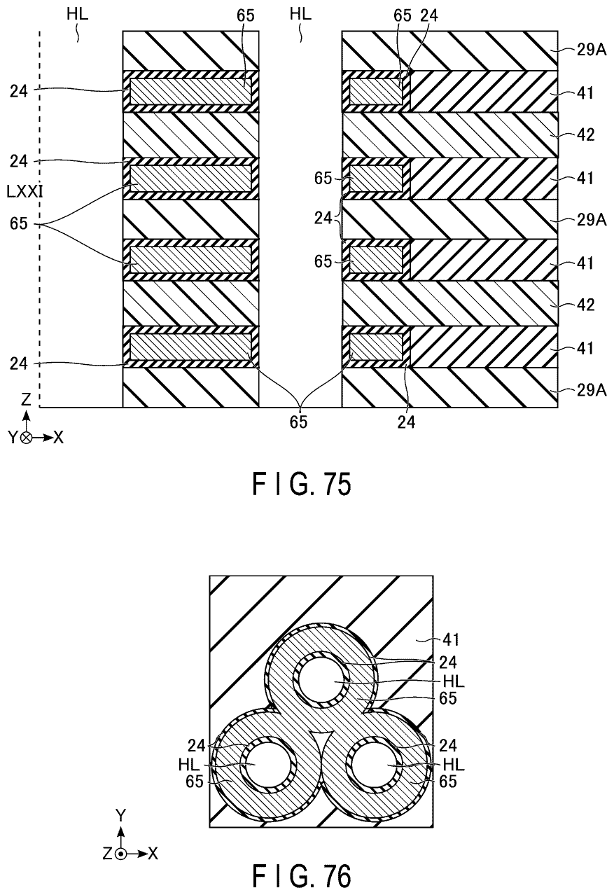

FIGS. 73 to 76 each illustrate a state during manufacturing of the memory device of the fifth embodiment. FIGS. 73 and 75 each illustrate the area illustrated in FIG. 70. FIGS. 74 and 76 each illustrate the area illustrated in FIG. 71.

First, the steps described above with reference to FIGS. 13, 14 and 15 of the manufacturing method of the first embodiment are executed.

As illustrated in FIGS. 73 and 74, a portion of the sacrificial material 41 which includes a surface exposed in the hole HL is removed. Thus, a space SP4 is formed in an area where the removed portion of the sacrificial material 41 was located. The space SP4 is connected to the hole HL. The space SP4 surrounds the hole HL along the xy plane. Examples of the removing method include wet etching. The space SP4 occupies an area where the conductor 65 and the insulator 24 are to be formed. Therefore, the shape of the space SP4 depends on the shape of the conductor 65 and the insulator 24. In the examples of FIGS. 73 and 74, a plurality of spaces SP4 connects adjacent holes HL to each other.

As illustrated in FIGS. 75 and 76, the insulator 24 and the conductor 65 are formed. The insulator 24 covers a surface of an element defining the space SP4. That is, the insulator 24 covers a surface of the insulator 29A exposed in the space SP4, a surface of the sacrificial material 42 exposed in the space SP4 and a surface of the sacrificial material 41 exposed in the space SP4. Examples of the forming method include CVD.

The conductor 65 is formed on the surface of the insulator 24. The conductor 65 fills an area of the space SP4 where the insulator 24 is not located. Examples of the forming method include CVD.

In addition, the remaining portion of the insulator 24 is formed on a surface of the conductor 65 exposed in the hole HL. Examples of the forming method include CVD.

The conductor 31 is formed by the same steps as those described above with reference to FIGS. 24 to 26 of the first embodiment.

The slit SLT is formed by the same steps as those described above with reference to FIGS. 27 to 29 of the first embodiment.

The sacrificial material 42 is removed by the same steps as those described above with reference to FIGS. 38 and 39 of the first embodiment, thereby forming the space SP3.

As illustrated in FIGS. 70, 71 and 72, the insulator 27 and the conductor 26 are formed by the same steps as those described above with reference to FIGS. 6, 7 and 8 of the first embodiment.

### 5.3. Advantages

Like the structure of the first embodiment, the structure of the fifth embodiment realizes a DRAM structure having a small-sized memory cell MC.

### 6. Sixth Embodiment

A sixth embodiment may be combined with the first, second, third, fourth or fifth embodiment. The following description relates to an example in which the sixth embodiment is based on the second embodiment.

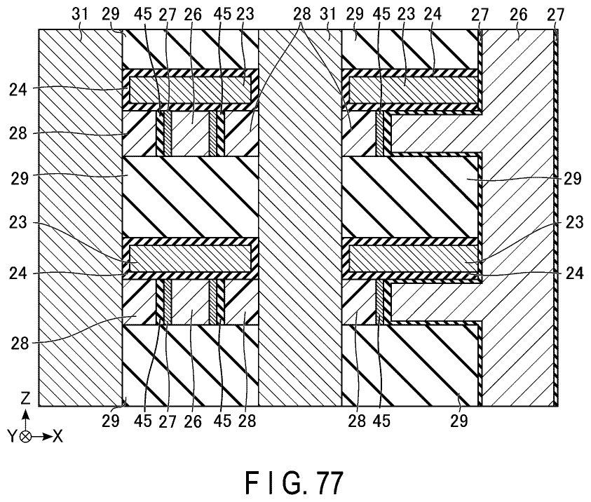

FIG. 77 illustrates a cross-sectional structure of part of a memory device of the sixth embodiment. FIG. 77 illustrates an area corresponding to the area illustrated in FIG. 6 of the first embodiment.

As illustrates in FIG. 77, the memory device 1 of the sixth embodiment includes neither the conductor 23 nor the insulator 24 in one sublayer SLA in each layer LA. An area of the sublayer SL including neither a conductor 23 nor an insulator 24 is provided with the insulator 29. FIG. 77 illustrates an example in which the lower sublayer SLA includes neither a conductor 23 nor an insulator 24.

Like the structure of the first embodiment, the structure of the sixth embodiment realizes a DRAM structure having a small-sized memory cell MC.

### 7. Seventh Embodiment

A seventh embodiment may be combined with the first, second, third, fourth, fifth or sixth embodiment. The following description relates to an example in which the seventh embodiment is based on the second embodiment.

### 7.1. Configuration

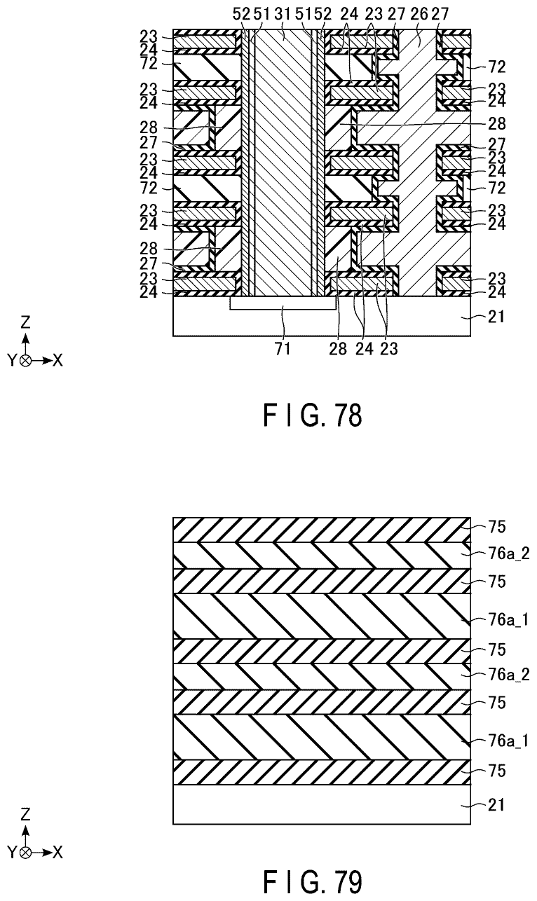

FIG. 78 illustrates a cross-sectional structure of part of a memory device of the seventh embodiment. FIG. 78 corresponds to the region illustrated in FIG. 6 of the first embodiment.

As illustrated in FIG. 78, the memory device 1 further includes an oxide region 71 in the substrate 21. The memory device 1 includes an insulator 72 instead of the insulator 29.

The oxide region 71 is located in an area including an upper surface of the substrate 21 and is located below a set of the conductors 31, 51 and 52. The oxidation region 71 includes an oxide of the material of the substrate 21.

Unlike in the first embodiment, in the seventh embodiment, the conductor 26 projects in a direction away from the center of the layer LB (where the insulator 72 is located). That is, the conductor 26 includes a portion located between two conductors 23 aligned in the Z direction in the layer LB. Based on this shape of the conductor 26, the insulator 27 also includes a portion located between the two conductors 23 aligned in the Z direction in the layer LB.

### 7.2. Manufacturing Method

FIGS. 79 to 93 each illustrate a state during manufacturing of the memory device of the seventh embodiment. FIGS. 79 to 93 illustrate the area illustrated in FIG. 78.

As illustrated in FIG. 79, a plurality of sacrificial materials 75 and a plurality of sacrificial materials 76a are formed on the substrate 21 alternately one by one in the Z direction.

The sacrificial material 75 occupies the layer where the sublayer SLA is to be located. In one example, the sacrificial materials 75 includes or substantially consists of silicon nitride. Examples of a method of forming the sacrificial materials 75 include CVD.

The sacrificial material 76a occupies the layer where the sublayer SLA is to be located and the layer where the layer LB is to be located. The sacrificial material 76a of the layer where the sublayer SLA is to be located may be referred to as sacrificial material 76a_1. The sacrificial material 76a of the layer where the layer LB is to be located may be referred to as sacrificial materials 76a_2. A thickness (the dimension thereof along the Z direction) of each of the sacrificial materials 76a_2 is smaller than that of the sacrificial material 76a_1. In one example, the sacrificial material 76a includes silicon oxide. Examples of a method of forming the sacrificial materials 76a include CVD.

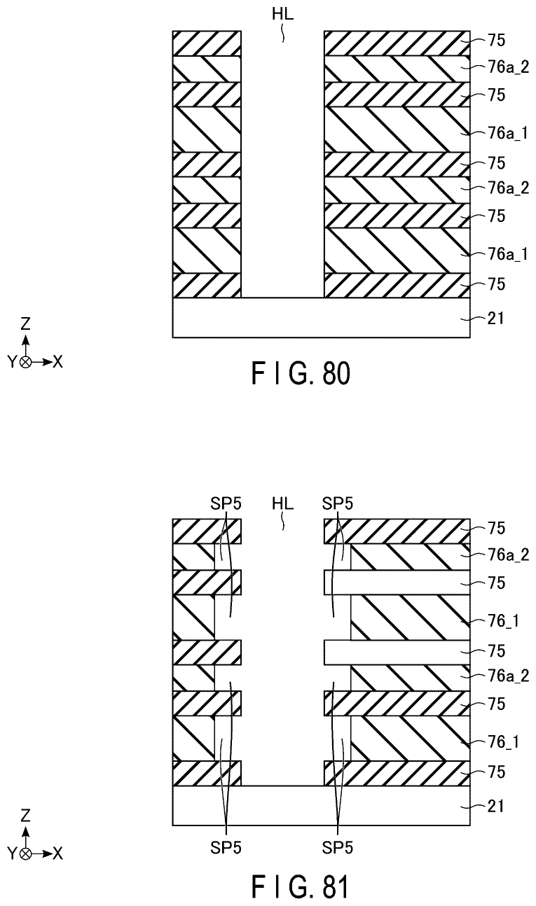

As illustrated in FIG. 80, a hole HL is formed. The hole HL extends in the Z direction and penetrates the sacrificial materials 75 and 76a. The sacrificial materials 75 and 76a are exposed in the hole HL. The substrate 21 is exposed to a bottom of the hole HL. Examples of the hole forming method include a combination of photolithography and anisotropic etching.

As illustrated in FIG. 81, a portion of sacrificial material 76a which includes a surface exposed in the hole HL is removed. Thus, a space SP5 is formed in an area where the removed portion of the sacrificial material 76a was located, and the sacrificial material 76_1 is formed from the sacrificial material 76a_1. The space SP5 is connected to the hole HL. The space SP5 surrounds the hole HL along the xy plane. Examples of the removing method include wet etching.

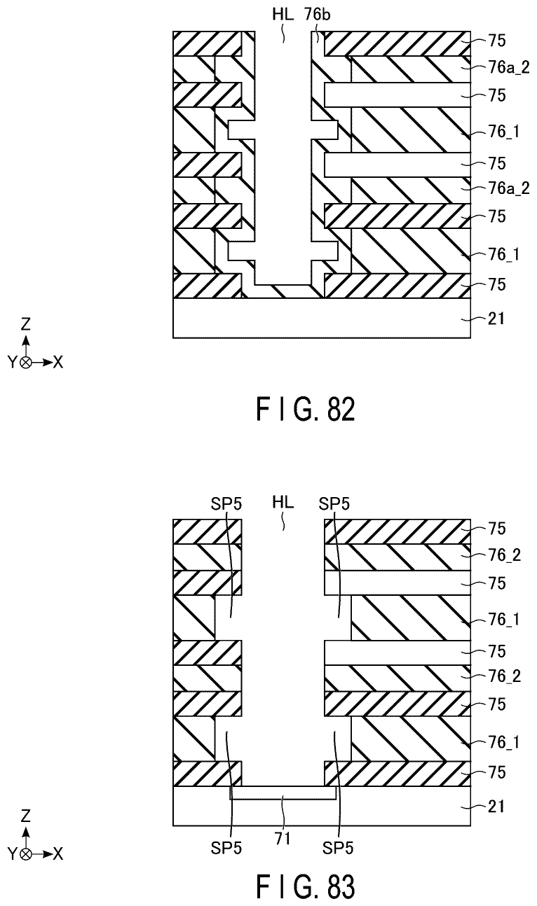

As illustrated in FIG. 82, a sacrificial material 76b is formed in the hole HL and space SP1. The sacrificial material 76b includes or substantially consists of the same material as that of the sacrificial materials 76a. The sacrificial material 76b covers a surface of an element defining the hole HL and a surface of an element defining the space SP1. That is, the sacrificial material 76b covers a surface of the sacrificial materials 75 which is exposed in the slit SLT and space SP5, a surface of the sacrificial material 76a which is exposed in the slit SLT and space SP5, and a surface of the substrate 21 which is exposed in the holes HL. Due to the difference in thickness between the sacrificial materials 76_1 and 76a_2, the sacrificial material 76b fills the space SP5 that is in contact with the sacrificial material 76a_2. On the other hand, due to the difference in thickness between the sacrificial materials 76_1 and 76a_2, the sacrificial material 76b does not fill the space SP5 that is in contact with the sacrificial material 76a_1, and the space SP5 that is in contact with the sacrificial material 76_1 partially remains. Examples of a method of depositing the sacrificial material 76b include CVD.

As illustrated in FIG. 83, the sacrificial material 76b is partially removed. Specifically, a portion of the sacrificial material 76b in the hole HL and a portion thereof that is in contact with the sacrificial material 76_1 are removed. Thus, the space SP5 is formed again in the layer where the sacrificial material 76_1 is located. Even after the removal, a portion of the sacrificial material 76b that is in contact with the sacrificial material 76a_2 remains. Thus, in the layer where the sacrificial material 76_2 is located, a sacrificial material 76_2 is formed by the remaining portions of the sacrificial material 76a_2 and sacrificial material 76b. Examples of the removing method include wet etching.

Then, the surface of the substrate 21 which is exposed in the hole HL is oxidized to form an oxide region 71.

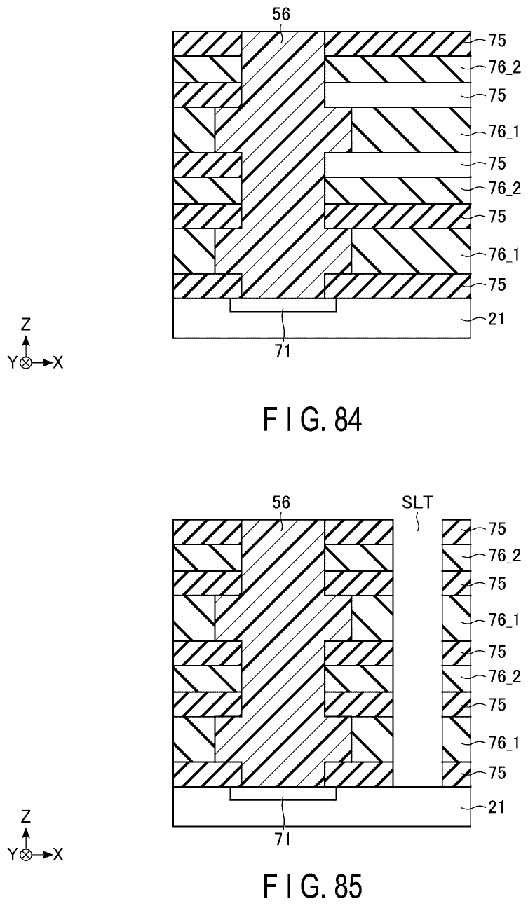

As illustrated in FIG. 84, a sacrificial material 56 is formed. The sacrificial material 56 fills the hole HL and the space SP5. Examples of the forming method include CVD.

As illustrated in FIG. 85, the slit SLT is formed by the same steps as those described above with reference to FIGS. 27, 28 and 29 of the first embodiment. The slit SLT extends in the Z direction and penetrates the sacrificial materials 75 and 76.

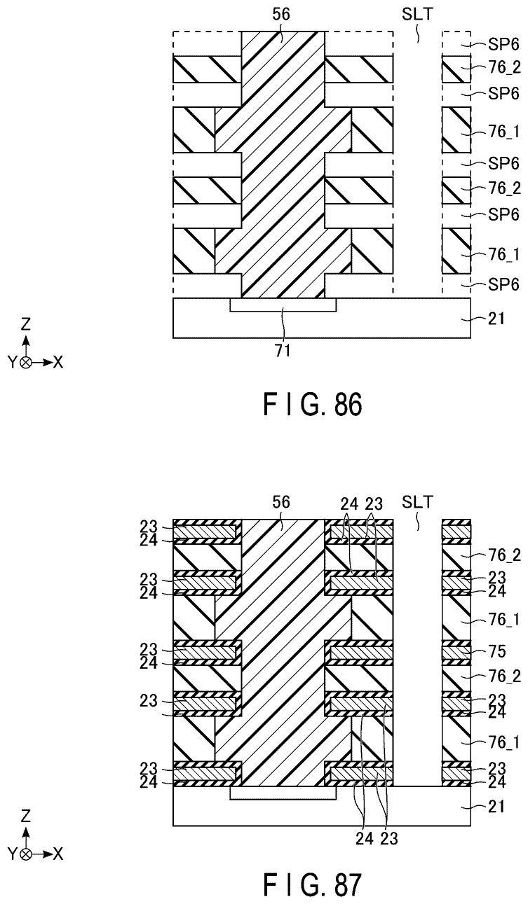

As illustrated in FIG. 86, the sacrificial material 75 is removed by the same steps as those described above with reference to FIGS. 30 and 31 of the first embodiment. Thus, a space SP6 is formed in the area where the sacrificial material 75 was located. The space SP6 is connected to the slit SLT. The space SP6 surrounds the hole HL along the xy plane. Examples of the removal include wet etching. A chemical for the wet etching reaches the sacrificial material 75 from the slit SLT to remove the sacrificial material 75.

As illustrated in FIG. 87, insulators 24 and conductors 23 are formed in the space SP6 by the same steps as those described above with reference to FIGS. 32 to 37 of the first embodiment. The insulator 24 covers a surface of an element defining the space SP6. That is, the insulator 24 covers a surface of the sacrificial material 76 which is exposed in the space SP6 and a surface of the sacrificial material 56 which is exposed in the space SP6. The conductor 23 is located on a surface of the insulator 24. A set of insulator 24 and conductor 23 fills the space SP6.

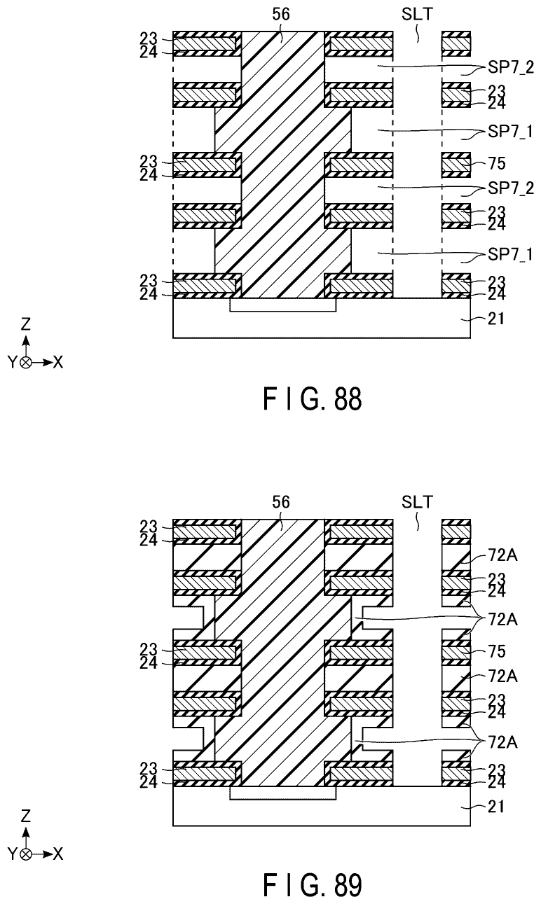

As illustrated in FIG. 88, the sacrificial materials 76_1 and 76_2 are removed. Thus, a space SP7_1 is formed in the area where the sacrificial material 76_1 was located, and a space SP7_2 is formed in the area where the sacrificial material 76_2 was located. A thickness of the space SP7_2 is larger than that of the space SP7_1. Examples of the removing method include wet etching.

As illustrated in FIG. 89, an insulator 72A is formed. The insulator 72A is an element that is to be formed into an insulator 72 by a later step. The insulator 72A substantially consists of the same material as that of the insulator 72. Due to the difference in thickness between spaces SP7_1 and SP7_2, the insulator 72A fills the space SP7_2. On the other hand, due to the difference in thickness between the spaces SP7_1 and SP7_2, the insulator 72A does not fill the space SP7_2 and the space SP7_2 partially remains. Examples of the forming method include CVD.

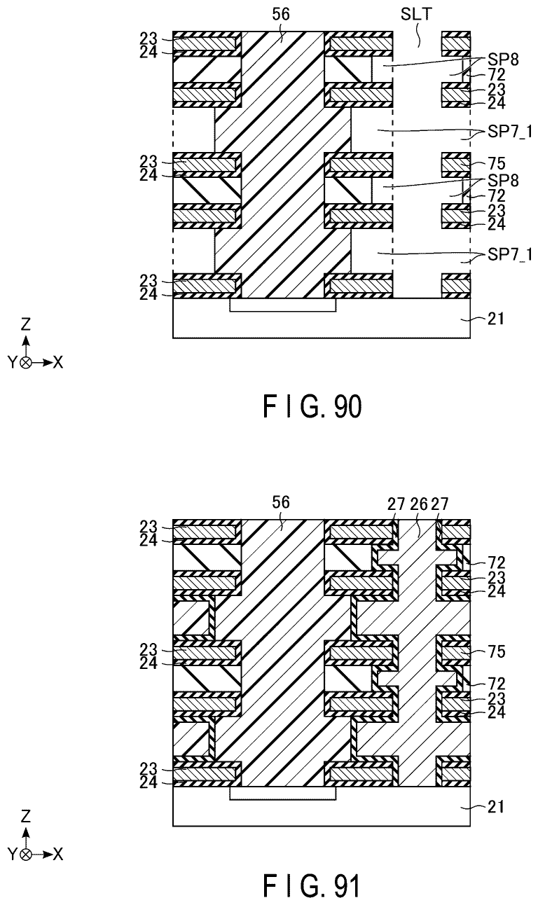

As illustrated in FIG. 90, the insulator 72A is partially removed. Specifically, a portion of the insulator 72A that includes an exposed surface is removed. Accordingly, the space SP7_1 is formed again. The space SP7_1 exposes the sacrificial material 56. In addition, by this removal, a portion of the insulator 72A that is filled in the space SP7_2 is removed. Thus, a space SP8 is formed in an area where the removed portion of the insulator 72A was located, and the insulator 72 is formed by the remaining portion of the insulator 72A. Examples of the removing method include wet etching.

As illustrated in FIG. 91, the insulator 27 and conductor 26 are formed by the same steps as those described above with reference to FIGS. 6, 7 and 8 of the first embodiment.

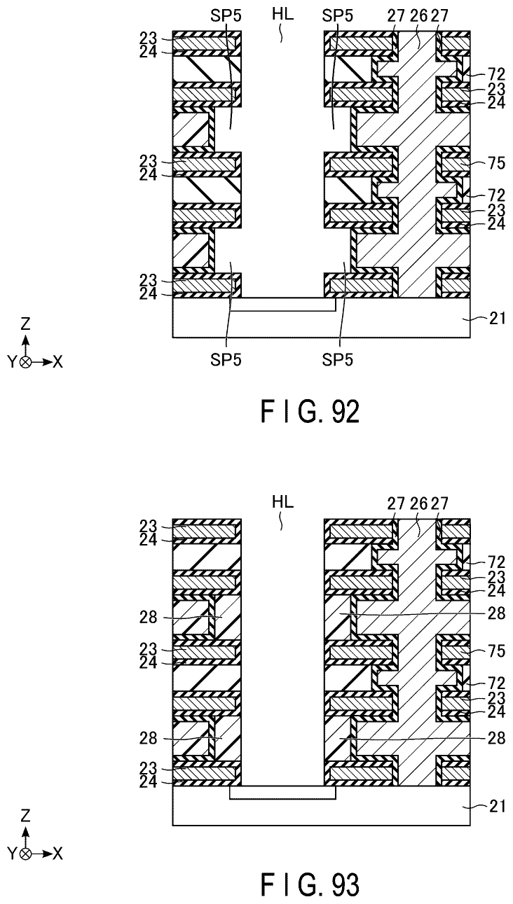

As illustrated in FIG. 92, the sacrificial material 56 is removed and accordingly the hole HL and the space SP5 are formed again. Examples of the removing method include wet etching. The space SP5 exposes the insulators 27.

As illustrated in FIG. 93, the semiconductor 28 is formed. That is, first, a semiconductor 28A is formed by the same steps as those described above with reference to FIGS. 45, 46 and 47 of the second embodiment. The semiconductor 28A filled the hole HL and the space SP5.

The semiconductor 28A is in contact with the insulator 27 in the space SP5. Then, a portion of the semiconductor 28A that is in the hole HL is removed by the same steps as those described above with reference to FIGS. 21, 22 and 23 of the first embodiment. Thus, the semiconductor 28 is formed from the remaining portion of the semiconductor 28A.

As illustrated in FIG. 78, the conductors 51, 52 and 31 are formed by the same steps as those described above with reference to FIGS. 49, 50 and 51 of the third embodiment.

### 7.3. Advantages

Like in the structure of the first embodiment, the structure of the seventh embodiment realizes a DRAM structure having a small-sized memory cell MC.

### 7.4. Modification

The insulator 24 may be formed after the step described above with reference to FIG. 92. In this case, only the conductor 23 is deposited by the step described above with reference to FIG. 87. Thus, the conductor 23 is exposed in the hole HL and the space SP5 by the step described above with reference to FIG. 92. After the step described above with reference to FIG. 92, the insulator 24 is deposited on a surface of an element defining the hole HL. Accordingly, the insulator 24 is deposited on a surface of the conductor 23 which is exposed in the hole HL and space SP5.

If the seventh embodiment is based on the third embodiment, the oxide semiconductor 48 is provided instead of the semiconductor 28.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a first conductor extending in a first direction;
a first semiconductor surrounding the first conductor along a first plane intersecting the first direction;
a first insulator surrounding the first semiconductor along the first plane;
a second conductor surrounding the first insulator along the first plane;
a third conductor located farther in the first direction than the first semiconductor and surrounding the first conductor along the first plane; and
a second insulator between the first semiconductor and the third conductor.

2. The memory device of claim 1, wherein the second conductor expands along the first plane.

3. The memory device of claim 1, wherein the third conductor expands along the first plane.

4. The memory device of claim 1, wherein the second conductor and the third conductor expand along the first plane and face each other along the first plane.

5. The memory device of claim 4, wherein:
the second insulator includes a first portion which is in contact with the third conductor and which expands along the first plane;
the first insulator includes a second portion which is in contact with the second conductor and which expands along the first plane; and
the first portion and the second portion are in contact with each other.

6. The memory device of claim 1, further comprising:
a second semiconductor located farther in the first direction than the third conductor and surrounding the first conductor along the first plane;
a third insulator surrounding the second semiconductor along the first plane;
a fourth conductor surrounding the third insulator along the first plane;
a fifth conductor located farther in the first direction than the second semiconductor and surrounding the first conductor along the first plane; and
a fourth insulator between the second semiconductor and the fifth conductor.

7. The memory device of claim 6, wherein:
the memory device further comprises a sixth conductor including a third portion extending in the first direction;
the second conductor and the fourth conductor are parts of the sixth conductor;
the memory device further comprises a fifth insulator including a fourth portion and a fifth portion which extend in the first direction;
the first insulator and the third insulator are parts of the fifth insulator;
the fourth portion is between the sixth conductor and the third conductor; and
the fifth portion is between the sixth conductor and the fifth conductor.

8. The memory device of claim 1, further comprising:
a seventh conductor extending in the first direction;
a third semiconductor surrounding the seventh conductor;
a sixth insulator surrounding the third semiconductor along the first plane; and
a seventh insulator between the third semiconductor and the third conductor,
wherein:
the second conductor further surrounds the sixth insulator along the first plane; and
the third conductor further surrounds the seventh conductor along the first plane.

9. The memory device of claim 1, further comprising:
an eighth conductor located farther in a fourth direction opposite to the first direction than the first semiconductor and surrounding the first conductor along the first plane; and
a second insulator between the first semiconductor and the eighth conductor.

10. The memory device of claim 1, further comprising a ninth conductor between the first semiconductor and the second conductor.

11. The memory device of claim 1, wherein the first semiconductor includes an oxide semiconductor.

12. The memory device of claim 1, wherein the first semiconductor includes an oxide including one or more elements of indium (In), gallium (Ga), zinc (Zn), tin (Sn), titanium (Ti), tungsten (W) and molybdenum (Mo).

13. The memory device of claim 12, further comprising:
a tenth conductor between the first semiconductor and the second conductor; and
an eleventh conductor between the tenth conductor and the second conductor.

14. The memory device of claim 12, further comprising:
a twelfth conductor between the first conductor and the first semiconductor; and
a thirteenth conductor between the twelfth conductor and the first semiconductor.

15. The memory device of claim 12, further comprising:
a tenth conductor between the first semiconductor and the second conductor;
an eleventh conductor between the tenth conductor and the second conductor;
a twelfth conductor between the first conductor and the first semiconductor; and
a thirteenth conductor between the twelfth conductor and the first semiconductor.

16. The memory device of claim 1, further comprising a ninth insulator provided between the first conductor and the first semiconductor and surrounded by the first semiconductor.

17. The memory device of claim 1, wherein the second insulator surrounds the third conductor along the first plane.

18. The memory device of claim 1, wherein:
during data write,
a first voltage is applied to the first conductor and the application of the first voltage is stopped,
the first voltage is applied to the second conductor, and
a second voltage is applied to the third conductor;
the first voltage is half a positive third voltage; and
the second voltage is lower than the third voltage.
